(19) United States
(12) Patent Application Publication
(10) Pub. No.: US 2025/0280714 A1
(43) Pub. Date: Sep. 4, 2025

(54) LIGHT EMITTING DEVICE, DISPLAY DEVICE, PHOTOELECTRIC CONVERSION DEVICE, ELECTRONIC APPARATUS, ILLUMINATION DEVICE, MOVING BODY, WEARABLE DEVICE, AND MANUFACTURING METHOD OF LIGHT EMITTING DEVICE

(71) Applicant: CANON KABUSHIKI KAISHA, Tokyo (JP)

(72) Inventor: AKIHIRO SHIMIZU, Kanagawa (JP)

(21) Appl. No.: 19/051,506

(22) Filed: Feb. 12, 2025

(30) Foreign Application Priority Data
Feb. 29, 2024 (JP) 2024-030644

(51) Int. Cl. H10K 59/80; H10K 59/12

(52) U.S. Cl. CPC H10K 59/878; H10K 59/1201; H10K 59/80518

(57) ABSTRACT

A light emitting device including a plurality of pixels is provided. Each of the plurality of pixels includes a first electrode arranged on a substrate, a second electrode arranged between the first electrode and the substrate, an organic functional layer including a light emitting layer arranged between the first electrode and the second electrode, and a reflective layer arranged between the second electrode and the substrate. The reflective layer has a first surface on a side of the second electrode, and a second surface on a side of the substrate, and an unevenness of the first surface is smaller than an unevenness of the second surface.

### BACKGROUND OF THE INVENTION

### Field of the Invention

The present disclosure relates to a light emitting device, a display device, a photoelectric conversion device, an electronic apparatus, an illumination device, a moving body, a wearable device, and a manufacturing method of the light emitting device.

### Description of the Related Art

A light emitting device including a light emitting element using an organic electroluminescence (EL) element is known. Japanese Patent Laid-Open No. 2021-072282 describes an organic device in which a reflective film is arranged between a semiconductor substrate and an organic functional film including an organic light emitting material layer to reflect, by the reflective film, light emitted from the organic functional film toward the semiconductor substrate.

### SUMMARY OF THE INVENTION

In order to improve the light emission efficiency of the light emitting device, it is necessary to improve the reflectance at the reflective film.

Some embodiments of the present disclosure provide a technique advantageous in improving the light emission efficiency.

According to some embodiments, a light emitting device comprising a plurality of pixels, wherein each of the plurality of pixels includes a first electrode arranged on a substrate, a second electrode arranged between the first electrode and the substrate, an organic functional layer including a light emitting layer arranged between the first electrode and the second electrode, and a reflective layer arranged between the second electrode and the substrate, the reflective layer has a first surface on a side of the second electrode, and a second surface on a side of the substrate, and an unevenness of the first surface is smaller than an unevenness of the second surface, is provided.

According to some other embodiments, a manufacturing method of a light emitting device including a plurality of pixels, comprising: preparing a substrate including a structure where a wiring pattern is arranged in an insulator; forming a first insulating layer on a support substrate; forming a reflective layer on the first insulating layer; forming, on the first insulating layer and the reflective layer, a bonding layer including a second insulating layer and a bonding pattern; bonding the structure and the bonding layer; exposing the first insulating layer by at least partially removing the support substrate after the bonding; and forming a first electrode, an organic functional layer, and a second electrode on the first insulating layer exposed by the exposing, is provided.

Further features of the present invention will become apparent from the following description of exemplary embodiments (with reference to the attached drawings).

### BRIEF DESCRIPTION OF THE DRAWINGS

FIG. 1 is a sectional view showing an example of the arrangement of a light emitting device according to an embodiment;

FIGS. 2A to 2D are sectional views showing a manufacturing method of the light emitting device shown in FIG. 1;

FIGS. 3A to 3D are sectional views showing the manufacturing method of the light emitting device shown in FIG. 1;

FIGS. 4A and 4B are sectional views showing the manufacturing method of the light emitting device shown in FIG. 1;

FIGS. 5A to 5C are sectional views showing the manufacturing method of the light emitting device shown in FIG. 1;

FIGS. 6A and 6B are sectional views showing the manufacturing method of the light emitting device shown in FIG. 1;

FIG. 7 is a sectional view showing a modification of the light emitting device shown in FIG. 1;

FIGS. 8A and 8B are sectional views showing a manufacturing method of the light emitting device shown in FIG. 7;

FIG. 9 is a sectional view showing a modification of the light emitting device shown in FIG. 1;

FIGS. 10A to 10E are sectional views showing a manufacturing method of the light emitting device shown in FIG. 9;

FIGS. 11A to 11C are sectional views showing the manufacturing method of the light emitting device shown in FIG. 9;

FIG. 12 is a sectional view showing the manufacturing method of the light emitting device shown in FIG. 9;

FIG. 13 is a sectional view showing a modification of the light emitting device shown in FIG. 1;

FIGS. 14A to 14D are sectional views showing a manufacturing method of the light emitting device shown in FIG. 13;

FIGS. 15A to 15D are sectional views showing the manufacturing method of the light emitting device shown in FIG. 13;

FIGS. 16A to 16C are sectional views showing the manufacturing method of the light emitting device shown in FIG. 13;

FIGS. 17A and 17B are sectional views showing an example of the arrangement of a pixel of the light emitting device shown in FIG. 1;

FIG. 18 is a view showing an example of a display device using the light emitting device according to the embodiment;

FIG. 19 is a view showing an example of a photoelectric conversion device using the light emitting device according to the embodiment;

FIG. 20 is a view showing an example of an electronic apparatus using the light emitting device according to the embodiment;

FIGS. 21A and 21B are views each showing an example of a display device using the light emitting device according to the embodiment;

FIG. 22 is a view showing an example of an illumination device using the light emitting device according to the embodiment;

FIG. 23 is a view showing an example of a moving body using the light emitting device according to the embodiment; and

FIGS. 24A and 24B are views each showing an example of a wearable device using the light emitting device according to the embodiment.

### DESCRIPTION OF THE EMBODIMENTS

Hereinafter, embodiments will be described in detail with reference to the attached drawings. Note, the following embodiments are not intended to limit the scope of the claimed invention. Multiple features are described in the embodiments, but limitation is not made to an invention that requires all such features, and multiple such features may be combined as appropriate. Furthermore, in the attached drawings, the same reference numerals are given to the same or similar configurations, and redundant description thereof is omitted.

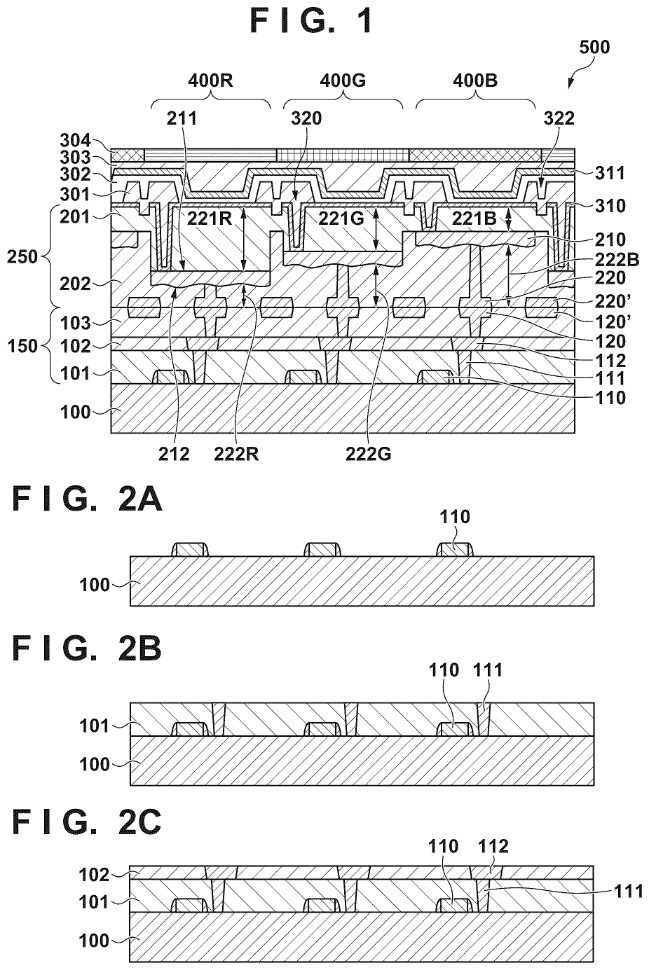

With reference to FIGS. 1 to 16, a light emitting device according to an embodiment of the present disclosure will be described. FIG. 1 is a sectional view showing an example of the arrangement of a light emitting device 500 according to this embodiment. The light emitting device 500 includes a plurality of pixels 400. Each of the plurality of pixels 400 includes an electrode 311 arranged on a substrate 100, an electrode 310 arranged between the electrode 311 and the substrate 100, an organic functional layer 302 including a light emitting layer arranged between the electrode 311 and the electrode 310, and a reflective layer 210 arranged between the electrode 310 and the substrate 100. The reflective layer 210 has a surface 211 on the electrode 310 side and a surface 212 on the substrate 100 side. As shown in FIG. 1, the unevenness of the surface 211 is smaller than the unevenness of the surface 212 in the reflective layer 210. The unevenness of the surface of the reflective layer 210 will be described using a manufacturing method to be described later. Here, the unevenness of each of the surfaces 211 and 212 can be checked by observation using a scanning electron microscope (SEM), a transmission electron microscope (TEM), or the like. For example, the unevenness of each of the surfaces 211 and 212 may be defined as surface roughness by using a scanning probe microscope (SPM/AFM) or the like. That is, it can also be said that the surface roughness of the surface 211 of the reflective layer 210 is smaller than the surface roughness of the surface 212. In this specification, surface roughness may be arithmetic mean roughness (Ra), maximum height (Rz), or root mean square roughness (Rms).

Each of the plurality of pixels 400 includes a transistor 110 arranged in the substrate 100. The transistor 110 is, for example, used to control light emission/non-light emission of the pixel 400, to control the light emission intensity, or the like. Each of the plurality of pixels 400 includes structures 150 and 250 which are arranged between the reflective layer 210 and the substrate 100 and in which a wiring pattern 112 and the like are arranged in insulators (insulating layers 101, 102, 103, and 202). In the arrangement shown in FIG. 1, the reflective layer 210 is electrically connected to the transistor 110 via the wiring pattern 112. Further, the reflective layer 210 is electrically connected to the electrode 310. Thus, an electric signal is transmitted from the transistor 110 arranged in the substrate 100 to the electrode 310, and the light emitting layer arranged in the organic functional layer 302 emits light with a predetermined luminance. The electrode 310 is isolated for each pixel 400 by an insulating layer 301. The insulating layer 301 can also be called a bank or the like.

An insulating layer 201 is arranged between the reflective layer 210 and the electrode 310. As shown in FIG. 1, the thickness of the insulating layer 201 may change among the pixels 400. The thickness of the insulating layer 201 may change in accordance with the color to be transmitted by a color filter 304 arranged for each pixel 400. For example, the thickness of the insulating layer 201 may be different between a pixel 400R and a pixel 400G. Further, the thickness of the insulating layer 201 in a pixel 400B may be different from the thickness of the insulating layer 201 in each of the pixel 400R and the pixel 400G. Here, the color filter 304 arranged in the pixel 400R may transmit red light, the color filter 304 arranged in the pixel 400G may transmit green light, and the color filter 304 arranged in the pixel 400B may transmit blue light.

Light emitted from the organic functional layer 302 (light emitting layer) toward the substrate 100 is reflected by the reflective layer 210. Light emitted from the organic functional layer 302 (light emitting layer) toward the electrode 311 and light reflected by the reflective layer 210 resonate and are amplified at a wavelength corresponding to each of thicknesses 221R, 221G, and 221B of the insulating layer 201 in the pixels 400R, 400G, and 400B, respectively. The amplified light is emitted from the pixel 400 through the color filter 304. Here, the thicknesses 221R, 221G, and 221B of the insulating layer 201 in the central portion of the reflective layer 210 in the pixels 400R, 400G, and 400B, respectively, are appropriately decided in consideration of the light amplification effect.

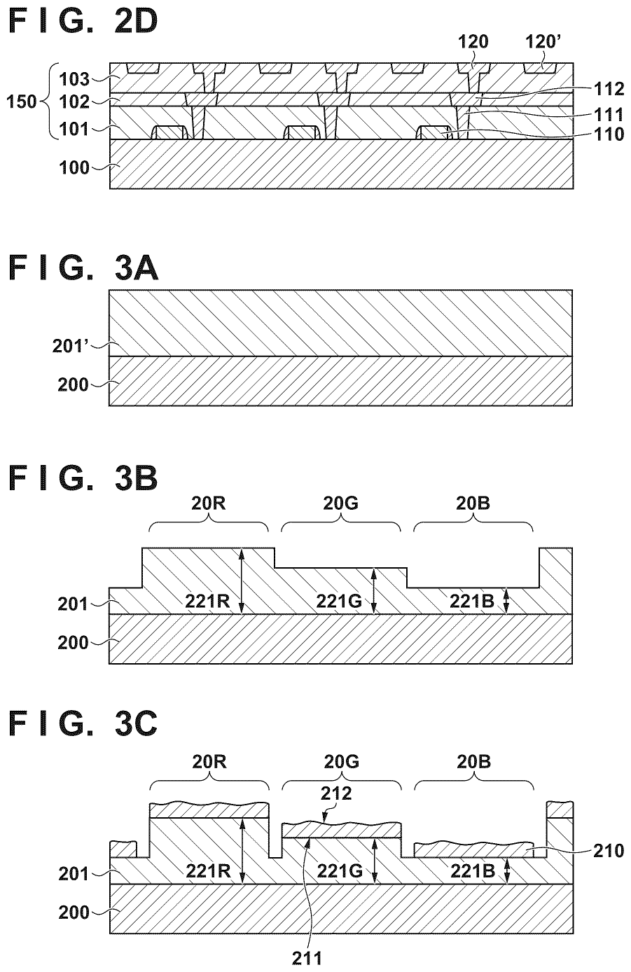

Next, a manufacturing method of the light emitting device 500 will be described. First, as shown in FIG. 2A, the transistors 110 each configured to control driving of the pixel 400 are formed in the substrate 100. Although not shown in the drawings, source and drain regions constituting the transistor 110, an element isolation region (for example, an STI structure) for electrically isolating the transistors 110, and the like can be formed in the substrate 100. For example, a semiconductor such as silicon can be used for the substrate 100.

After the transistors 110 are formed, the insulating layer 101 is formed on the substrate 100. The insulating layer 101 can be, for example, BPSG deposited by a thermal CVD method, silicon oxide deposited by a plasma CVD method, or the like. The insulating layer 101 may have a single layer structure, or a stacked layer structure constituted by a plurality of layers. After the insulating layer 101 is formed, a conductor is embedded in each opening portion formed in the insulating layer 101 using a photolithography step and a dry etching step. Furthermore, by using a planarization step, a dry etching step, or the like, conductive plugs 111 are formed as shown in FIG. 2B. The conductive plug 111 may be, for example, a tungsten plug including a barrier metal layer made of Ti/TiN or the like.

Then, the insulating layer 102 is formed on the insulating layer 101. The insulating layer 102 may have a single layer structure, or a stacked layer structure constituted by a plurality of layers. For the insulating layer 102, for example, silicon oxide, silicon nitride, silicon oxynitride, silicon oxycarbide, silicon oxyfluoride, or the like is used. Then, a conductor is embedded in each opening portion provided in the insulating layer 102 using a photolithography step and a dry etching step, and the wiring pattern 112 is formed as shown in FIG. 2C by using a planarization step or the like. The wiring pattern 112 is electrically connected to the transistor 110 via the conductive plug 111. The wiring pattern 112 may be, for example, a copper wiring pattern including a barrier metal layer made of TaCu or the like. Alternatively, the wiring pattern may be an aluminum wiring pattern including a barrier metal layer made of Ti/TiN or the like. If an aluminum wiring pattern is used as the wiring pattern 112, after the wiring pattern 112 patterned by a photolithography step and a dry etching step is formed, the insulating layer 102 may be formed on the insulating layer 101 and the wiring pattern 112.

Then, the insulating layer 103 is formed on the insulating layer 102. The insulating layer 103 may have a single layer structure, or a stacked layer structure constituted by a plurality of layers. For the insulating layer 103, for example, silicon oxide, silicon nitride, silicon oxynitride, silicon oxycarbide, silicon oxyfluoride, or the like is used. A conductor is embedded in each opening portion provided in the insulating layer 103 using a photolithography step and a dry etching step. Furthermore, by using a planarization step or the like, a bonding pattern 120 and a dummy bonding pattern 120′ are formed as shown in FIG. 2D. Here, the bonding pattern 120 is electrically connected to the wiring pattern 112, and the dummy bonding pattern 120′ is insulated without electrical connection. Each of the bonding pattern 120 and the dummy bonding pattern 120′ can be, for example, a copper wiring pattern including a barrier metal layer made of TaCu or the like. The bonding pattern 120 and the dummy bonding pattern 120′ are arranged at an appropriate density. The insulating layer 103 where the bonding pattern 120 and the dummy bonding pattern 120′ are arranged can also be called a bonding layer.

Through the steps described above, the substrate 100 is prepared that includes the structure 150 where the wiring pattern 112 is arranged in the insulator (insulating layers 101, 102, and 103). In the arrangement shown in FIG. 2D, the wiring pattern 112 is arranged only in one wiring layer, but the present invention is not limited to this, and two or more wiring layers may be arranged.

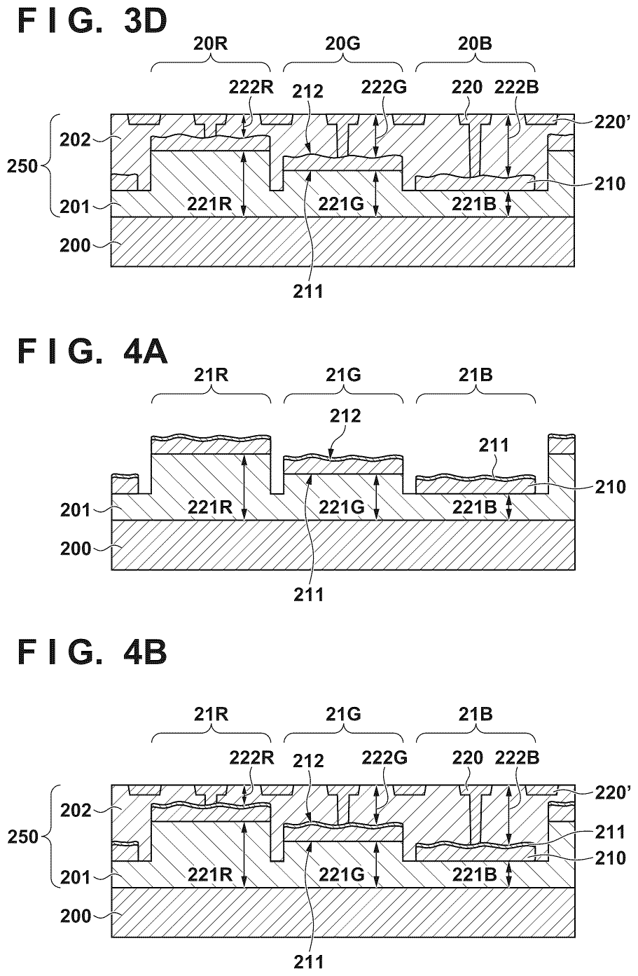

FIGS. 3A to 3D show steps for forming the structure 250 including the reflective layer 210. The steps for forming the structure 250 may be performed in parallel with the steps for forming the structure 150 on the substrate 100 shown in FIGS. 2A to 2D, or may be performed in an appropriate order.

First, as shown in FIG. 3A, a material layer 201′ of the insulating layer 201 is formed on a support substrate 200. A semiconductor such as silicon may be used for the support substrate 200. However, the material used for the support substrate 200 is not limited to a semiconductor such as silicon. Another appropriate material may be used for the support substrate 200 as long as it can support the structure 250 and can be removed in a step to be described later. The material layer 201′ of the insulating layer 201 is formed of a light transmissive insulator. The material layer 201′ of the insulating layer 201 may have a single layer structure, or a stacked layer structure constituted by a plurality of layers. For the material layer 201′ of the insulating layer 201, for example, silicon oxide, silicon nitride, silicon oxynitride, or the like can be used.

After the material layer 201′ of the insulating layer 201 is formed, as shown in FIG. 3B, the insulating layer 201 is formed using a photolithography step, a dry etching step, and the like. The insulating layer 201 is formed so as to have the thicknesses 221R, 221G, and 221B in regions 20R, 20G, and 20B where the pixels 400R, 400G, and 400B are to be formed, respectively. That is, the insulating layer 201 is formed by etching the material layer 201′ so as to have different film thicknesses in a portion constituting the pixel 400R, a portion constituting the pixel 400G, and a portion constituting the pixel 400B in the material layer 201′ of the insulating layer 201. For example, when an insulator of the thickness 221R is deposited as the material layer 201′ of the insulating layer 201, only the regions 20G and 20B may be etched using a photolithography step, a dry etching step, and the like to form the insulating layer 201. Since the insulating layer 201 functions as an optical adjustment film as described above, the thickness changes among the regions 20R, 20G, and 20B.

Then, a reflective material is deposited on the insulating layer 201, and the reflective layer 210 is formed using a photolithography step and a dry etching step as shown in FIG. 3C. For the reflective layer 210, for example, a high reflectance material such as aluminum, silver, or platinum, or an alloy containing such material can be used. Particularly, aluminum or an alloy containing aluminum as a main component may be used for the reflective layer 210 since it is easy to increase the resolution. In the contact surface between the reflective layer 210 and the insulating layer 201, for example, a barrier metal layer made of Ti/TiN or the like may be formed.

In the section shown in FIG. 3C, the surface 212 of the reflective layer 210 as the surface after the deposition, which is not in contact with the insulating layer 201, is formed to have unevenness. On the other hand, the unevenness (surface roughness) of the surface 211 of the reflective layer 210, which is in contact with the insulating layer 201, is smaller than the unevenness (surface roughness) of the surface 212 which is not in contact with the insulating layer 201. This is so because the unevenness of the upper surface of the insulating layer 201, on which the reflective layer 210 is formed, has a higher planarity than the surface 212 as the surface after the reflective layer 210 is formed.

In the steps shown in FIGS. 3B and 3C, the material layer 201′ of the insulating layer 201 is etched to appropriate thicknesses for the regions 20R, 20G, and 20B, and then the reflective layer 210 is formed. However, the present invention is not limited to this. An insulating layer having the thickness 221B may be formed, and then an insulating layer may be formed so as to have the thickness 221G in the region other than the region 20B. Further, an insulating layer may be formed to have the thickness 221R in the region other than the regions 20G and 20B, thereby forming the insulating layer 201. In this case, the reflective layer 210 may be formed after the insulating layer 201 is formed, or the reflective layer 210 may be formed for each of the regions 20R, 20G, and 20B at the time when each insulating layer having a predetermined thickness is formed.

Then, by using a deposition step, a planarization step, and the like, the insulating layer 202 is formed to cover the insulating layer 201 and the reflective layer 210. The insulating layer 202 may have a single layer structure, or a stacked layer structure constituted by a plurality of layers. For the insulating layer 202, for example, silicon oxide, silicon nitride, silicon oxynitride, silicon oxycarbide, silicon oxyfluoride, or the like can be used. Here, the insulating layer 202 is planarized such that the insulating layer 202 formed on the reflective layer 210 has thicknesses 222R, 222B, and 222G in the regions 20R, 20G, and 20B, respectively.

After the insulating layer 202 is formed, a conductor is embedded in each opening portion provided in the insulating layer 202 using a photolithography step and a dry etching step. Furthermore, by using a planarization step or the like, a bonding pattern 220 and a dummy bonding pattern 220′ are formed as shown in FIG. 3D. Here, the bonding pattern 220 is electrically connected to the reflective layer 210, and the dummy bonding pattern 220′ is insulated without electrical connection. A plurality of the bonding patterns 220 may be arranged for one reflective layer 210. Each of the bonding pattern 220 and the dummy bonding pattern 220′ can be, for example, a copper wiring pattern including a barrier metal layer made of TaCu or the like. The bonding pattern 220 and the dummy bonding pattern 220′ are arranged at an appropriate density. The insulating layer 202 where the bonding pattern 220 and the dummy bonding pattern 220′ are arranged can also be called a bonding layer.

Through the steps described above, the structure 250 including the reflective layer 210 is formed on the support substrate 200. In the arrangement shown in FIG. 3D, only the reflective layer 210, the bonding pattern 220, and the dummy bonding pattern 220′ are arranged in the structure 250. However, the present invention is not limited to this, and one or more wiring layers including a wiring pattern may be formed between the reflective layer 210 and the bonding pattern 220 (dummy bonding pattern 220′).

Here, a modification of the structure 250 will be described with reference to FIGS. 4A and 4B. A description of the arrangement that may be similar to the arrangement of the structure 250 described above will appropriately be omitted, and different arrangement will mainly be described.

After the insulating layer 201 is formed as shown in FIG. 3B, a reflective material for forming the reflective layer 210 and a material for forming a conductive layer 213 are deposited on the insulating layer 201. Then, by using a photolithography step and a dry etching step, the reflective layer 210 and the conductive layer 213, which is arranged to be in contact with the surface 212 of the reflective layer 210 and cover the surface 212, are formed as shown in FIG. 4A. A material similar to the above-described material is used for the reflective layer 210. An appropriate conductive material is used for the conductive layer 213. For example, the conductive layer 213 may be a barrier metal layer made of Ti/TiN or the like. Also in the section shown in FIG. 4A, the unevenness of the surface 211 of the reflective layer 210 in contact with the insulating layer 210 is smaller than the unevenness of the surface 212 not in contact with the insulating layer 201.

Then, by using a deposition step, a planarization step, and the like, the insulating layer 202 is formed to cover the insulating layer 201, the reflective layer 210, and the conductive layer 213. The insulating layer 202 may have a single layer structure, or a stacked layer structure constituted by a plurality of layers. For the insulating layer 202, for example, silicon oxide, silicon nitride, silicon oxynitride, silicon oxycarbide, silicon oxyfluoride, or the like can be used. Here, the insulating layer 202 is planarized such that the insulating layer 202 formed on the reflective layer 210 has thicknesses 222R, 222B, and 222G in the regions 20R, 20G, and 20B, respectively.

After the insulating layer 202 is formed, a conductor is embedded in each opening portion provided in the insulating layer 202 using a photolithography step and a dry etching step. Furthermore, by using a planarization step or the like, the bonding pattern 220 and the dummy bonding pattern 220′ are formed as shown in FIG. 4B. Here, the bonding pattern 220 is electrically connected to the reflective layer 210, and the dummy bonding pattern 220′ is insulated without electrical connection. A plurality of the bonding patterns 220 may be arranged for one reflective layer 210. Each of the bonding pattern 220 and the dummy bonding pattern 220′ can be, for example, a copper wiring pattern including a barrier metal layer made of TaCu or the like. The bonding pattern 220 and the dummy bonding pattern 220′ are arranged at an appropriate density. Through the steps described above, the structure 250 including the reflective layer 210 is formed on the support substrate 200.

For example, consider a case where the reflective layer 210 is made of copper-containing aluminum (AlCu). In this case, if an opening is formed from the insulating layer 202 to the reflective layer 210 by a dry etching step or the like, the aluminum of the exposed reflective layer 210 is oxidized, and aluminum oxide can be formed in the surface 212 of the reflective layer 212. Since aluminum oxide is an insulator, it can cause a conductive failure. Therefore, the conductive layer 213 made of TiN or the like which hardly reacts with oxygen is arranged to cover the surface 212 of the reflective layer 210. With this, a conductive failure occurring when electrically connecting the reflective layer 210 and the bonding pattern 220 is suppressed. In the arrangement shown in FIGS. 4A and 4B, the conductive layer 213 is arranged to cover the entire surface 212 of the reflective layer 210. However, the present invention is not limited to this, and the conductive layer 213 may be arranged to partially cover the surface 212 of the reflective layer 210. More specifically, it is sufficient that the conductive layer 213 is arranged between the reflective layer 210 and the bonding pattern 220. In the light emitting device 500 shown in FIG. 1, the conductive layer 213 is arranged between the substrate 100 and the reflective layer 210.

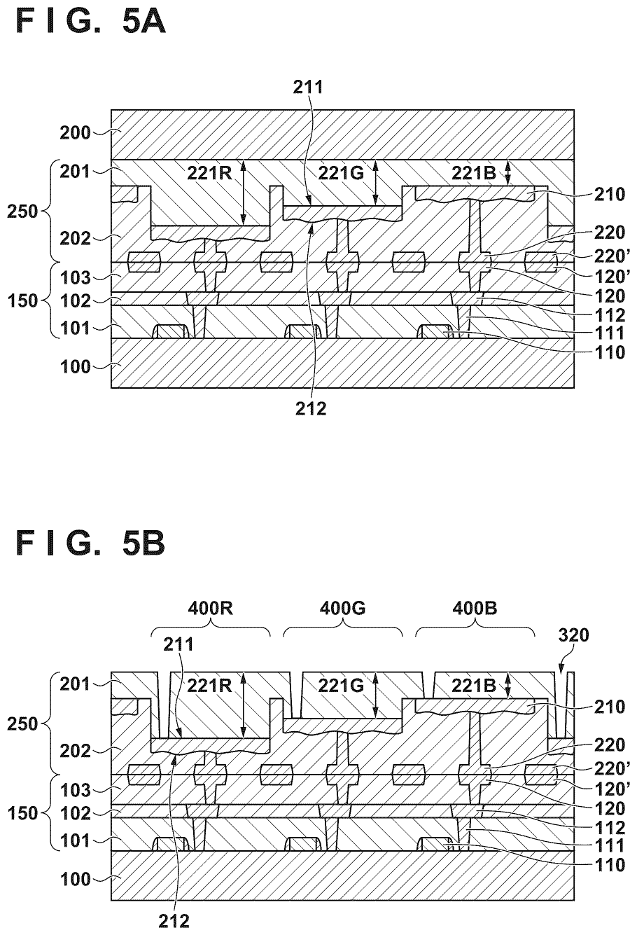

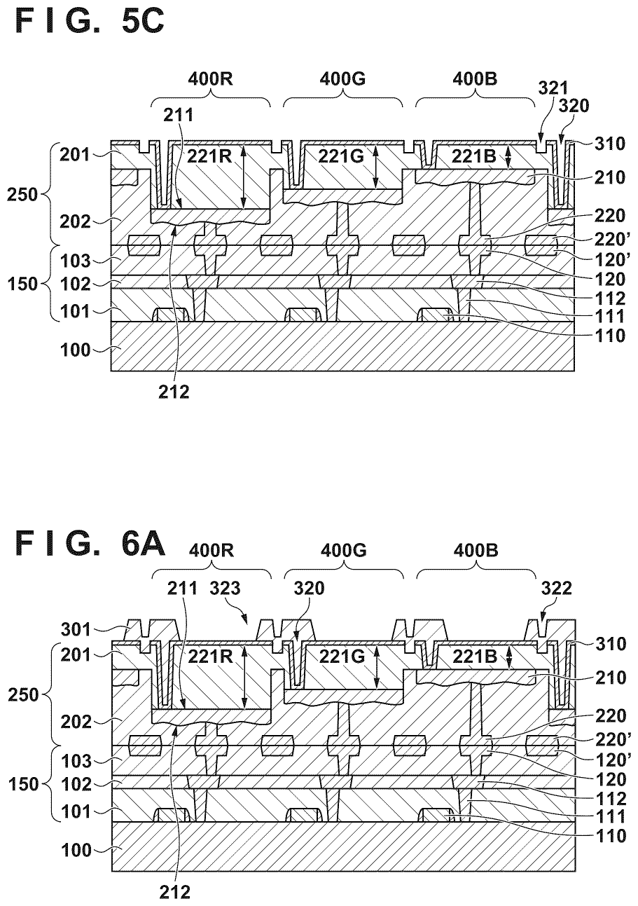

Then, a bonding step of the structure 150 formed on the substrate 100 and the structure 250 formed on the support substrate 200 and including the reflective layer 210 is performed as shown in FIG. 5A. In the following steps, the structure shown in FIG. 3D is shown as the structure 250, but the conductive layer 213 shown in FIG. 4B may be arranged therein.

In a step shown in FIG. 5A, the insulating layer 103 (bonding layer) forming the surface of the structure 150 and the insulating layer 202 (bonding layer) forming the surface of the structure 250 are bonded. As shown in FIG. 5A, for example, the structure 250 is placed on the structure 150, and heat treatment or the like is performed to bond them. At this time, the bonding pattern 120 of the structure 150 and the bonding pattern 220 of the structure 250 are bonded to each other. Similarly, the dummy bonding pattern 120′ of the structure 150 and the dummy bonding pattern 220′ of the structure 250 are bonded to each other. By connecting the bonding pattern 120 and the bonding pattern 220 to each other, the transistor 110 for controlling driving of the pixel 400 and the reflective layer 210 are electrically connected.

Then, a step of removing the support substrate 200 is performed. The support substrate 200 is removed at least partially, more specifically, at least in the region where the pixel 400 is arranged, to expose the insulating layer 201. The support substrate 200 may entirely be removed. For example, a film thinning step is used to remove the support substrate 200. Examples of the film thinning step for removing the support substrate 200 are a back grinding step, a chemical mechanical polishing step, and an etching step.

Then, steps are performed in which the electrode 310, the organic functional layer 302 including the light emitting layer, and the electrode 311 are formed on the insulating layer 201 exposed by removing the support substrate 200 and performing an exposing step of exposing the insulating layer 201. First, as shown in FIG. 5B, an opening portion 320 is formed to extend through the insulating layer 210 in the peripheral portion of the reflective layer 201. The opening portion 320 is formed using a photolithography step and a dry etching step. As shown in FIG. 5B, the depth of the opening portion 320 is equal to the corresponding one of the thicknesses 221R, 221G, and 221B of the insulating layer 201. Thus, the reflective layer 210 is exposed.

After the opening portion 320 is formed, the electrode 310 is formed on the insulating layer 201. The electrode 310 is formed of a transparent material. For example, indium tin oxide, indium zinc oxide, or the like can be used for the electrode 310. The electrode 310 is electrically connected to the peripheral portion of the reflective layer 210 via the opening portion 320. The electrode 310 can also be called a lower electrode. After the electrode 310 is formed, as shown in FIG. 5C, an opening portion 321 is formed using a photolithography step and a dry etching step to insulate the electrodes 310 of the adjacent pixels 400 from each other.

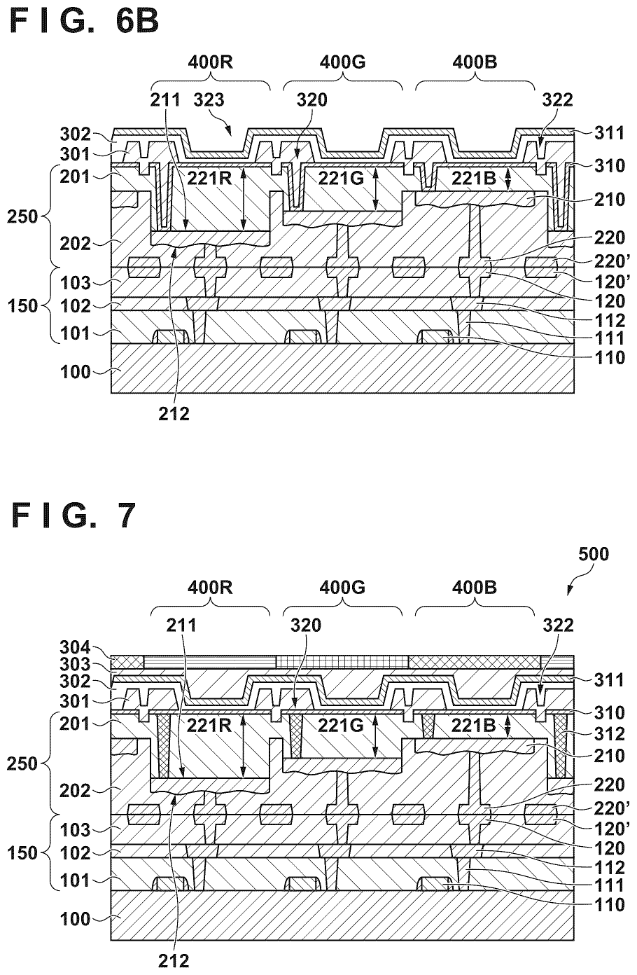

Then, as shown in FIG. 6A, the insulating layer 301 including opening portions 322 and opening portions 323 is formed on the electrode 310 by using a photolithography step and a dry etching step. For example, silicon oxide, silicon nitride, silicon oxynitride, silicon oxycarbide, silicon oxyfluoride, or the like can be used for the insulating layer 301. The insulating layer 301 is arranged to electrically insulate the electrodes 310 respectively arranged to correspond to the pixels 400 from each other. To suppress a leakage current to the adjacent pixel 400, the opening portion 322 is arranged to surround the pixel 400 in a planar view. If a leakage current to the adjacent pixel 400 can be suppressed only by the opening portion 323 defining the light emission region of the pixel 400, the opening portion 322 may not be formed.

After the insulating layer 301 is formed, as shown in FIG. 6B, the organic functional layer 302 and the electrode 311 are formed to cover the insulating layer 301 and the electrode 310. The organic functional layer 302 includes at least an organic light emitting material layer, and may additionally include a charge transport layer, a charge block layer, and the like. The organic functional layer 302 may be continuously arranged to cover the multiple pixels 400R, 400G, and 400B. When the organic functional layer 302 is continuously arranged, it can be said that the organic functional layer 302 is continuous among the pixels 400, the organic functional layer 302 is arranged across the multiple pixels 400, or the multiple pixels 400 share one organic functional layer 302.

The electrode 311 is made of a transparent material to transit light generated in the organic functional layer 302. The electrode 311 may reflect part of light generated in the organic functional layer 302 to the reflective layer 210 side. For the electrode 311, for example, a thin film of a metal such as magnesium or silver or an alloy containing such material as a main component material can be used. The electrode 311 can also be called an upper electrode.

Then, a sealing layer 303 is formed on the electrode 311. The sealing layer 303 is arranged to prevent permeation of moisture into respective components of the light emitting device 500 such as the substrate 100, the organic functional layer 302, and the electrode 311. The sealing layer 303 may have a single layer structure, or a stacked layer structure constituted by a plurality of layers. For example, silicon nitride, aluminum oxide, or the like can be used for the sealing layer 303. The color filters 304 are formed on the sealing layer 303 as shown in FIG. 1. The color filters 304 may transmit different colors in the pixel 400R, the pixel 400G, and the pixel 400B. Although not shown in FIG. 1, a microlens may be formed on the color filter 304. For example, a planarization layer or the like may be formed between the color filter 304 and the sealing layer 303.

As described above, light emitting from the organic functional layer 302 (light emitting layer) toward the substrate 100 is reflected by the reflective layer 210, and resonates and is amplified at a wavelength corresponding to each of the thicknesses 221R, 221G, and 221B of the insulating layer 201 in the pixels 400R, 400G, and 400B, respectively. Therefore, in order to improve the light emission efficiency of the light emitting device 500, it is necessary to improve the reflectance at the reflective layer 210. In the light emitting device 500 formed by the steps described with reference to FIGS. 1 to 6B, the reflective layer 210 is formed on the insulating layer 201 for an interference structure that resonates and amplifies light. Accordingly, the surface 211 of the reflective layer 210, which is the reflective surface of the interference structure in the light emitting device 500, is the interface with the insulating layer 201. Since the unevenness of the upper surface of the insulating layer 201, on which the reflective layer 210 is formed, has a higher planarity than the surface 212 as the surface after the reflective layer 210 is formed, the unevenness of the surface 211 of the reflective layer 210 in contact with the insulating layer 201 is smaller than the unevenness of the surface 212 not in contact with the insulating layer 201. Hence, for example, as compared to a case where the reflective layer 210 is formed on the insulating layer 202 and then the insulating layer 201 is formed, the reflectance at the reflective layer 210 can be improved. As a result, the light emission efficiency of the light emitting device 500 can be improved.

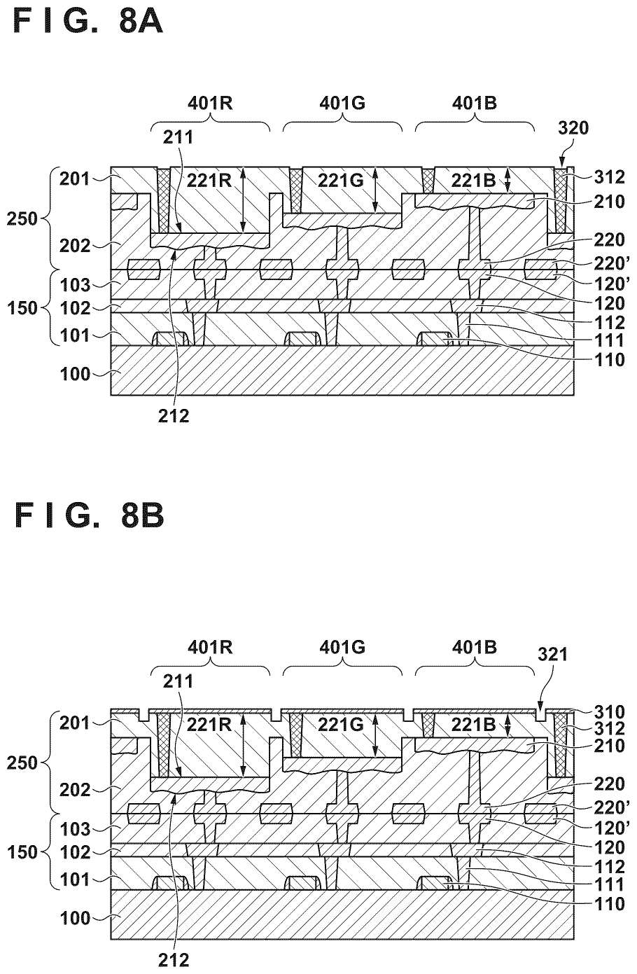

Next, a modification of the light emitting device 500 shown in FIG. 1 will be described with reference to FIGS. 7 to 8B. The arrangement different from the above-described embodiment will mainly be described, and a description of the arrangement that may be similar to the above-described embodiment will appropriately be omitted.

In the light emitting device 500 shown in FIG. 1, the electrode 310 and the insulating layer 301 are embedded in the opening portion 320 provided in the insulating layer 201. On the other hand, in the light emitting device 500 shown in FIG. 7, a conductive plug 312 is embedded in the opening portion 320. The electrode 310 is connected to the reflective layer 210 via the conductive plug 312. This has an effect of simplifying the step of forming the electrode 310 as compared to the structure shown in FIG. 1.

After the opening portion 320 is formed as shown in FIG. 5B, a conductor is embedded in each opening portion 320 as shown in FIG. 8A, and the conductive plug 312 is formed using a planarization step, a dry etching step, or the like. The conductive plug 312 can be, for example a tungsten plug including a barrier metal layer such as Ti/TiN, or the like.

Then, the electrode 310 is formed to cover the insulating layer 201 and the conductive plug 312. The electrode 310 is electrically connected to the peripheral portion of the reflective layer 210 via the conductive plug 312. Further, by using a photolithography step and a dry etching step, the opening portion 321 is formed as shown in FIG. 8B to insulate the electrodes 310 of the adjacent pixels 400 from each other. The subsequent steps can be similar to the above-described steps from FIG. 6A.

Also in this embodiment, the unevenness (surface roughness) of the surface 211 of the reflective layer 210, which is in contact with the insulating layer 201, is smaller than the unevenness (surface roughness) of the surface 212 which is not in contact with the insulating layer 201. This can improve the reflectance at the reflective layer 210, thereby improving the light emission efficiency of the light emitting device 500.

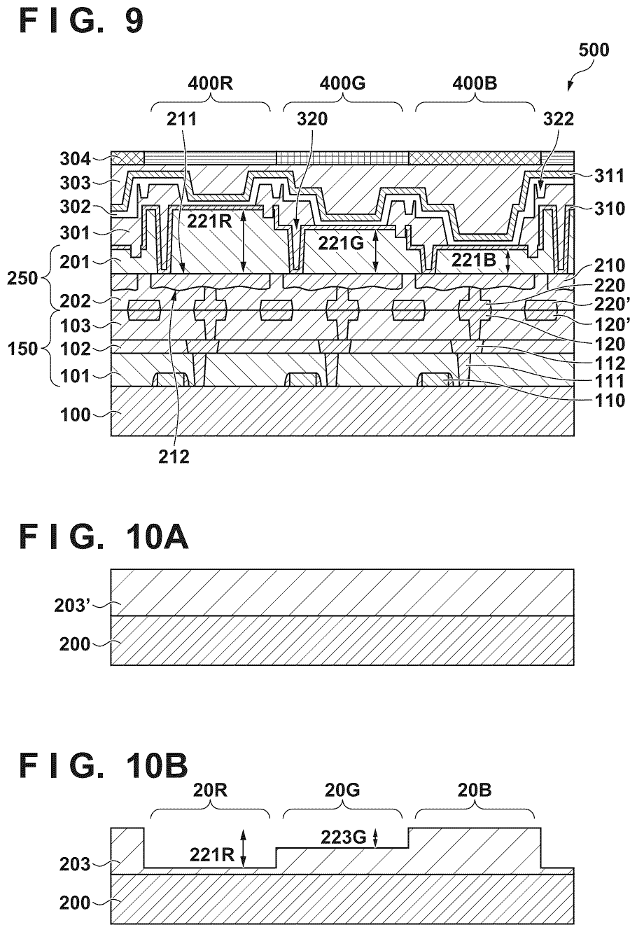

Next, a modification of the light emitting device 500 shown in each of FIGS. 1 and 7 will be described with reference to FIGS. 9 to 12. The arrangement different from the above-described embodiment will mainly be described, and a description of the arrangement that may be similar to the above-described embodiment will appropriately be omitted.

In the arrangement shown in each of FIGS. 1 and 7, the distance between the reflective layer 210 and the substrate 100 in the pixel 400R is different from the distance between the reflective layer 210 and the substrate 100 in the pixel 400G. Similarly, the distance between the reflective layer 210 and the substrate 100 in the pixel 400B is different from the distance between the reflective layer 210 and the substrate 100 in each of the pixel 400R and the pixel 400G. On the other hand, in the arrangement shown in FIG. 9, the difference between the distance between the reflective layer 210 and the substrate 100 in the pixel 400R and the distance between the reflective layer 210 and the substrate 100 in the pixel 400G is smaller than the difference between the thickness of the insulating layer 201 arranged between the electrode 310 and the reflective layer 210 in the pixel 400R and the thickness of the insulating layer 201 in the pixel 400G. In addition, the difference between the distance between the reflective layer 210 and the substrate 100 in the pixel 400R and the distance between the reflective layer 210 and the substrate 100 in the pixel 400B is smaller than the difference between the thickness of the insulating layer 201 in the pixel 400R and the thickness of the insulating layer 201 in the pixel 400B. Similarly, the difference between the distance between the reflective layer 210 and the substrate 100 in the pixel 400G and the distance between the reflective layer 210 and the substrate 100 in the pixel 400B is smaller than the difference between the thickness of the insulating layer 201 in the pixel 400G and the thickness of the insulating layer 201 in the pixel 400B. For example, the distance between the reflective layer 210 and the substrate 100 in the pixel 400R, the distance between the reflective layer 210 and the substrate 100 in the pixel 400G, and the distance between the reflective layer 210 and the substrate 100 in the pixel 400B may be the same. A manufacturing method of the light emitting device 500 shown in FIG. 9 will be described below. Since steps for forming the structure 150 on the substrate 100 may be similar to the steps described with reference to FIGS. 2A to 2D, a description will be started from steps for forming the structure 250 on the support substrate 200.

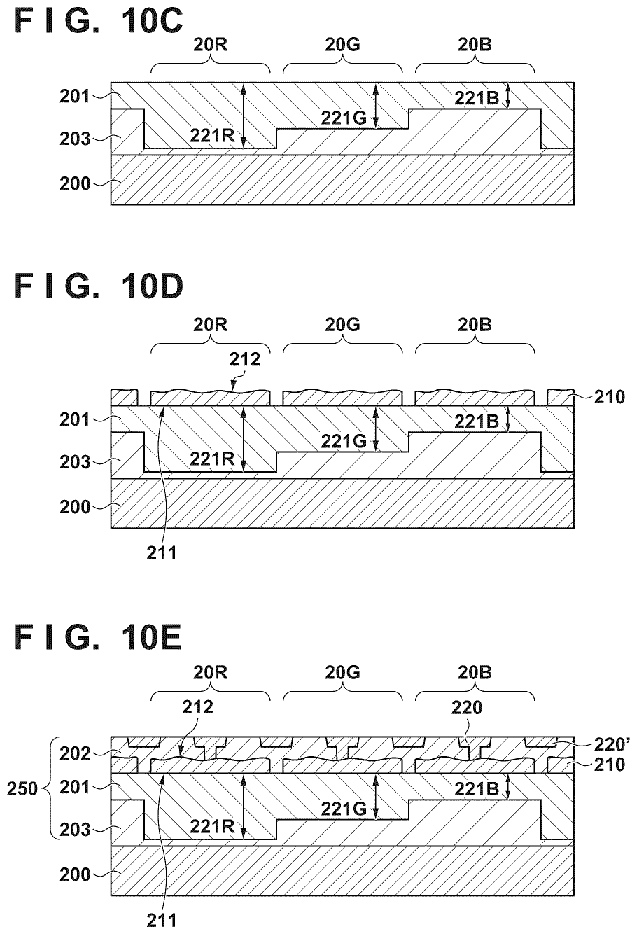

First, as shown in FIG. 10A, a material layer 203′ of a structure layer 203 is formed on the support substrate 200. For the material layer 203′ of the structure layer 203, for example, silicon nitride, silicon oxynitride, silicon oxide, silicon oxycarbide, silicon oxyfluoride, or the like can be used.

After the material layer 203′ of the structure layer 203 is formed, as shown in FIG. 10B, the structure layer 203 is formed using a photolithography step, a dry etching step, and the like. The structure layer 203 is formed so as to have thicknesses 223R, 223G, and 223B in the regions 20R, 20G, and 20B corresponding to the pixels 400R, 400G, and 400B, respectively. That is, the structure layer 203 is formed by etching the material layer 203′ so as to have different film thicknesses in a portion corresponding to the pixel 400R, a portion corresponding to the pixel 400G, and a portion corresponding to the pixel 400B in the material layer 203′ of the structure layer 203.

Then, as shown in FIG. 10C, the insulating layer 201 is formed on the structure layer 203 by using a deposition step, a planarization step, and the like. The insulating layer 201 is formed so as to have the thicknesses 221R, 221G, and 221B in the regions 20R, 20G, and 20B where the pixels 400R, 400G, and 400B are to be formed, respectively. The insulating layer 201 is formed of a light transmissive insulator. For the insulating layer 201, for example, silicon oxide, silicon nitride, silicon oxynitride, or the like can be used. Here, materials for the structure layer 203 and the insulating layer 201 can be selected such that a sufficient difference in etching rate (selectivity) can be obtained in the etching step of the structure layer 203 to be described later.

Then, a reflective material is deposited on the insulating layer 201, and the reflective layer 210 is formed using a photolithography step and a dry etching step as shown in FIG. 10D. For the reflective layer 210, for example, a high reflectance material such as aluminum, silver, or platinum, or an alloy containing such material can be used. Particularly, aluminum or an alloy containing aluminum as a main component may be used for the reflective layer 210 since it is easy to increase the resolution. In the contact surface between the reflective layer 210 and the insulating layer 201, for example, a barrier metal layer made of Ti/TiN or the like may be formed.

As shown in FIG. 10D, the unevenness of the surface 211 of the reflective layer 210, which is in contact with the insulating layer 201, is smaller than the unevenness of the surface 212 which is not in contact with the insulating layer 201. As in the above-described embodiment, this is so because the unevenness of the upper surface of the insulating layer 201, on which the reflective layer 210 is formed, has a higher planarity than the surface 212 as the surface after the reflective layer 210 is formed.

Then, by using a deposition step, a planarization step, and the like, the insulating layer 202 is formed to cover the insulating layer 201 and the reflective layer 210. The insulating layer 202 may have a single layer structure, or a stacked layer structure constituted by a plurality of layers. For the insulating layer 202, for example, silicon oxide, silicon nitride, silicon oxynitride, silicon oxycarbide, silicon oxyfluoride, or the like can be used.

After the insulating layer 202 is formed, a conductor is embedded in each opening portion provided in the insulating layer 202 using a photolithography step and a dry etching step. Furthermore, by using a planarization step or the like, the bonding pattern 220 and the dummy bonding pattern 220′ are formed as shown in FIG. 10E. Here, the bonding pattern 220 is electrically connected to the reflective layer 210, and the dummy bonding pattern 220′ is insulated without electrical connection. A plurality of the bonding patterns 220 may be arranged for one reflective layer 210. Each of the bonding pattern 220 and the dummy bonding pattern 220′ can be, for example, a copper wiring pattern including a barrier metal layer made of TaCu or the like. The bonding pattern 220 and the dummy bonding pattern 220′ are arranged at an appropriate density.

Through the steps described above, the structure 250 including the reflective layer 210 is formed on the support substrate 200. In the arrangement shown in FIG. 10E, only the reflective layer 210, the bonding pattern 220, and the dummy bonding pattern 220′ are arranged in the structure 250. However, the present invention is not limited to this, and one or more wiring layers including a wiring pattern may be formed between the reflective layer 210 and the bonding pattern 220 (dummy bonding pattern 220′). The conductive layer 213 as shown in FIGS. 4A and 4B may be arranged to cover the surface 212 of the reflective layer 210.

In this embodiment, the reflective layers 210 are formed on the same plane as shown in FIG. 10D. This facilitates formation of the bonding pattern 220 and the dummy bonding pattern 220′ shown in subsequent FIG. 10E, so that it has an effect of suppressing a bonding failure. In FIGS. 10D and 10E, only multiple reflective layers 210 and bonding patterns 220 are shown, but a plurality of wiring layers may be formed therebetween.

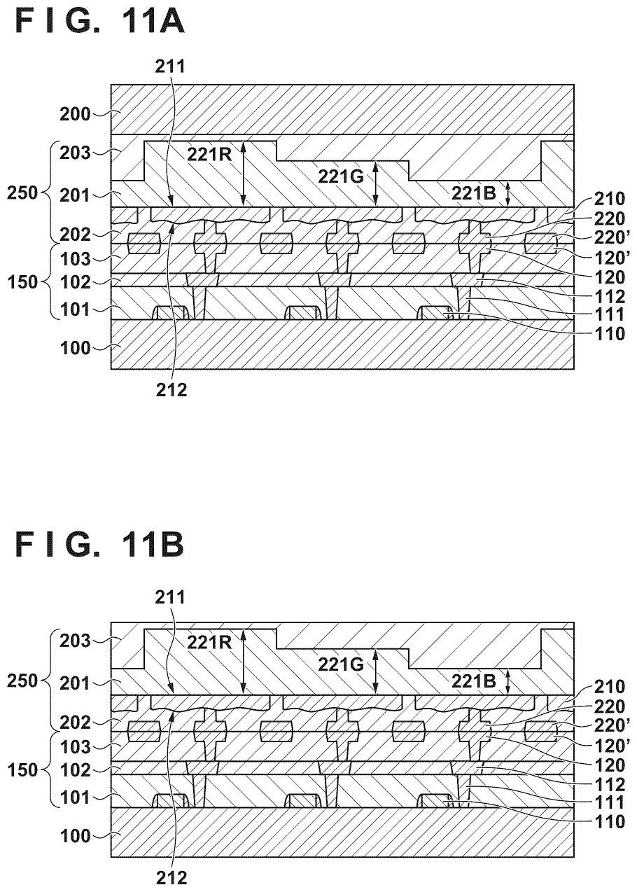

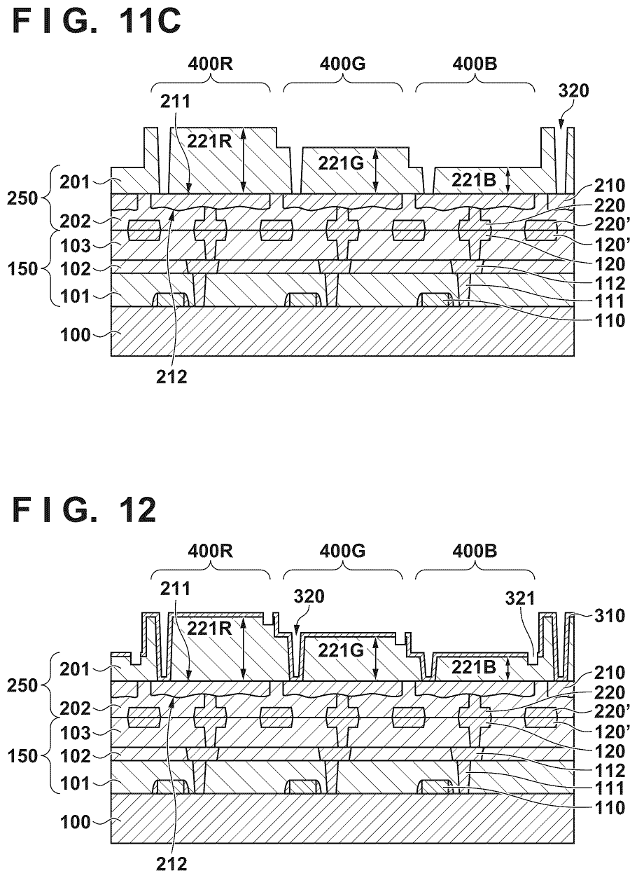

Then, a bonding step of the structure 150 formed on the substrate 100 and the structure 250 formed on the support substrate 200 and including the reflective layer 210 is performed as shown in FIG. 11A. In a step shown in FIG. 11A, the insulating layer 103 (bonding layer) forming the surface of the structure 150 and the insulating layer 202 (bonding layer) forming the surface of the structure 250 are bonded. As shown in FIG. 11A, for example, the structure 250 is placed on the structure 150, and heat treatment or the like is performed to bond them. At this time, the bonding pattern 120 of the structure 150 and the bonding pattern 220 of the structure 250 are bonded to each other. Similarly, the dummy bonding pattern 120′ of the structure 150 and the dummy bonding pattern 220′ of the structure 250 are bonded to each other. By bonding the bonding pattern 120 and the bonding pattern 220 to each other, the transistor 110 for controlling driving of the pixel 400 and the reflective layer 210 are electrically connected.

Then, as shown in FIG. 11B, a step of removing the support substrate 200 is performed. The support substrate 200 is removed at least partially, more specifically, at least in the region where the pixel 400 is arranged. The support substrate 200 may entirely be removed. For example, a film thinning step is used to remove the support substrate 200. Examples of the film thinning step for removing the support substrate 200 are a back grinding step, a chemical mechanical polishing step, and an etching step.

After the support substrate 200 is removed, a step of removing the structure layer 203 by using a wet etching step or the like is performed. The structure layer 203 is removed at least partially, more specifically, at least in the region where the pixel 400 is arranged, to expose the insulating layer 201. The structure layer 203 may entirely be removed. It is possible to selectively remove the structure layer 203 by selecting materials different in etching rate for the insulating layer 201 and the structure layer 203. For example, a chemical solution such as phosphoric acid or nitrohydrofluoric acid can be used in the wet etching step. For example, when silicon oxide is used as the insulating layer 201 and silicon nitride is used as the structure layer 203, the structure layer 203 can be selectively removed by using phosphoric acid as the chemical solution.

After the insulating layer 201 is exposed, as shown in FIG. 11C, the opening portion 320 is formed to extend through the insulating layer 210 in the peripheral portion of the reflective layer 201. The opening portion 320 is formed using a photolithography step and a dry etching step. As shown in FIG. 11C, the depth of the opening portion 320 is equal to the corresponding one of the thicknesses 221R, 221G, and 221B of the insulating layer 201. Thus, the reflective layer 210 is exposed.

Then, the electrode 310 is formed on the insulating layer 201. The electrode 310 is formed of a transparent material. For example, indium tin oxide, indium zinc oxide, or the like can be used for the electrode 310. The electrode 310 is electrically connected to the peripheral portion of the reflective layer 210 via the opening portion 320. As shown in FIG. 7, the conductive plug 312 may be embedded in each opening portion 320, and the electrode 310 may be formed thereon. After the electrode 310 is formed, as shown in FIG. 12, the opening portion 321 is formed using a photolithography step and a dry etching step to insulate the electrodes 310 of the adjacent pixels 400 from each other. The subsequent steps may be similar to the steps from FIG. 6A, and a description thereof will be omitted.

Also in this embodiment, the unevenness (surface roughness) of the surface 211 of the reflective layer 210, which is in contact with the insulating layer 201, is smaller than the unevenness (surface roughness) of the surface 212 which is not in contact with the insulating layer 201. This can improve the reflectance at the reflective layer 210, thereby improving the light emission efficiency of the light emitting device 500.

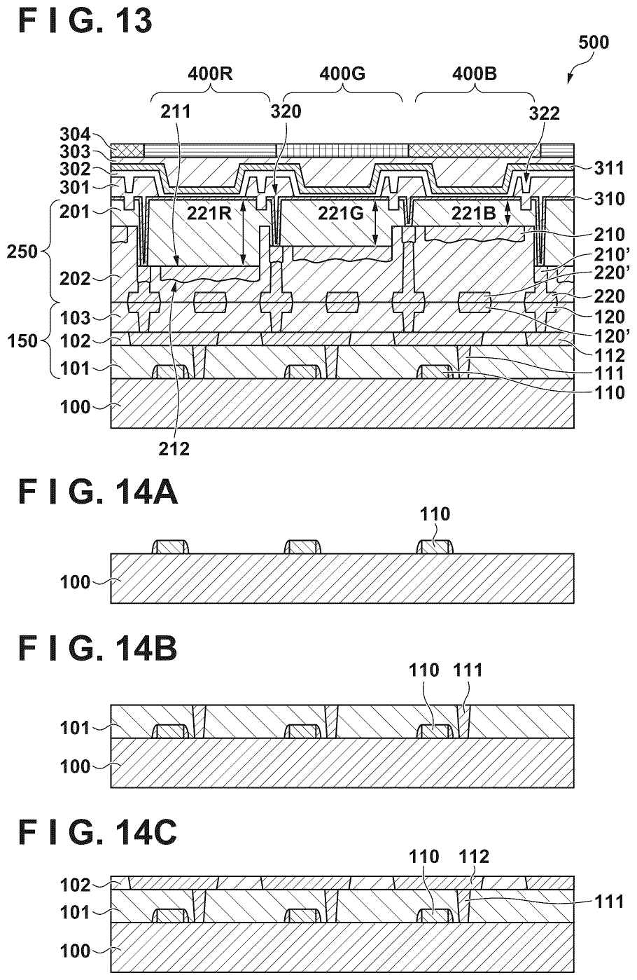

Next, a further modification of the light emitting device 500 shown in FIG. 1 will be described with reference to FIGS. 13 to 16. The arrangement different from the above-described embodiment will mainly be described, and a description of the arrangement that may be similar to the above-described embodiment will appropriately be omitted.

In the arrangement shown in each of FIGS. 1, 7, and 9, the transistor 110 and the electrode 310 are electrically connected via the reflective layer 210. Accordingly, the reflective layer 210 is electrically connected to the transistor via the wiring pattern 112. On the other hand, in the arrangement shown in FIG. 13, a conductive pattern 210′ arranged on the side of the insulating layer 202 opposite to the substrate 100 and electrically connected to the electrode 310 is arranged in the pixel 400. The conductive pattern 210′ is electrically connected to the transistor 110 via the wiring pattern 112. As a result, the transistor 110 and the electrode 310 are electrically connected. The conductive pattern 210′ can be a pattern that is simultaneously formed with the reflective layer 210 as will be described later. Accordingly, the reflective layer 210 and the conductive pattern 210′ can contain the same material. The reflective layer 210 and the conductive pattern 210′ may be formed of the same material. It can also be said that, in each pixel 400, the conductive pattern 210′ is arranged in a layer having the same distance from the substrate 100 as the reflective layer 210. A manufacturing method of the light emitting device 500 shown in FIG. 13 will be described below.

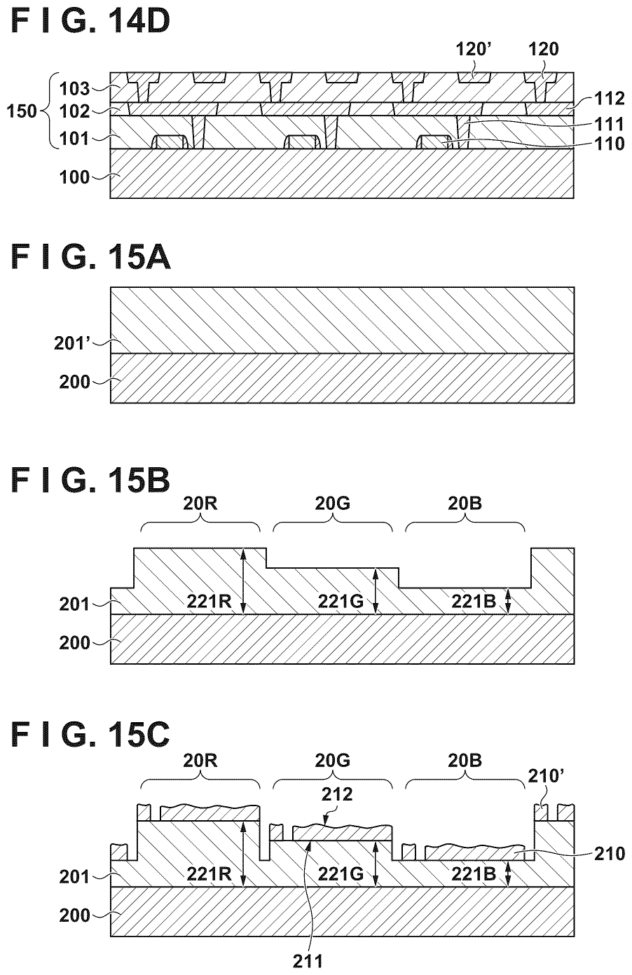

First, as shown in FIG. 14A, the transistors 110 each configured to control driving of the pixel 400 are formed in the substrate 100. Although not shown in the drawings, source and drain regions constituting the transistor 110, an element isolation region (for example, an STI structure) for electrically isolating the transistors 110, and the like can be formed in the substrate 100. For example, a semiconductor such as silicon can be used for the substrate 100.

After the transistors 110 are formed, the insulating layer 101 is formed on the substrate 100. The insulating layer 101 can be, for example, BPSG deposited by a thermal CVD method, silicon oxide deposited by a plasma CVD method, or the like. The insulating layer 101 may have a single layer structure, or a stacked layer structure constituted by a plurality of layers. After the insulating layer 101 is formed, a conductor is embedded in each opening portion formed in the insulating layer 101 using a photolithography step and a dry etching step. Furthermore, by using a planarization step, a dry etching step, or the like, the conductive plugs 111 are formed as shown in FIG. 14B. The conductive plug 111 may be, for example, a tungsten plug including a barrier metal layer made of Ti/TiN or the like.

Then, the insulating layer 102 is formed on the insulating layer 101. The insulating layer 102 may have a single layer structure, or a stacked layer structure constituted by a plurality of layers. For the insulating layer 102, for example, silicon oxide, silicon nitride, silicon oxynitride, silicon oxycarbide, silicon oxyfluoride, or the like is used. Then, a conductor is embedded in each opening portion provided in the insulating layer 102 using a photolithography step and a dry etching step, and the wiring pattern 112 is formed as shown in FIG. 14C using a planarization step or the like. The wiring pattern 112 is electrically connected to the transistor 110 via the conductive plug 111. The wiring pattern 112 may be, for example, a copper wiring pattern including a barrier metal layer made of TaCu or the like. Alternatively, the wiring pattern may be an aluminum wiring pattern including a barrier metal layer made of Ti/TiN or the like. If an aluminum wiring pattern is used as the wiring pattern 112, after the wiring pattern 112 patterned by a photolithography step and a dry etching step is formed, the insulating layer 102 may be formed on the insulating layer 101 and the wiring pattern 112.

Then, the insulating layer 103 is formed on the insulating layer 102. The insulating layer 103 may have a single layer structure, or a stacked layer structure constituted by a plurality of layers. For the insulating layer 103, for example, silicon oxide, silicon nitride, silicon oxynitride, silicon oxycarbide, silicon oxyfluoride, or the like is used. A conductor is embedded in each opening portion provided in the insulating layer 103 using a photolithography step and a dry etching step. Furthermore, by using a planarization step or the like, the bonding pattern 120 and the dummy bonding pattern 120′ are formed as shown in FIG. 14D. Here, the bonding pattern 120 is electrically connected to the wiring pattern 112, and the dummy bonding pattern 120′ is insulated without electrical connection. Each of the bonding pattern 120 and the dummy bonding pattern 120′ can be, for example, a copper wiring pattern including a barrier metal layer made of TaCu or the like. The bonding pattern 120 and the dummy bonding pattern 120′ are arranged at an appropriate density.

Through the steps described above, the substrate 100 is prepared that includes the structure 150 where the wiring pattern 112 is arranged in the insulator (insulating layers 101, 102, and 103). In the arrangement shown in FIG. 14D, the wiring pattern 112 is arranged only in one wiring layer, but the present invention is not limited to this, and two or more wiring layers may be arranged.

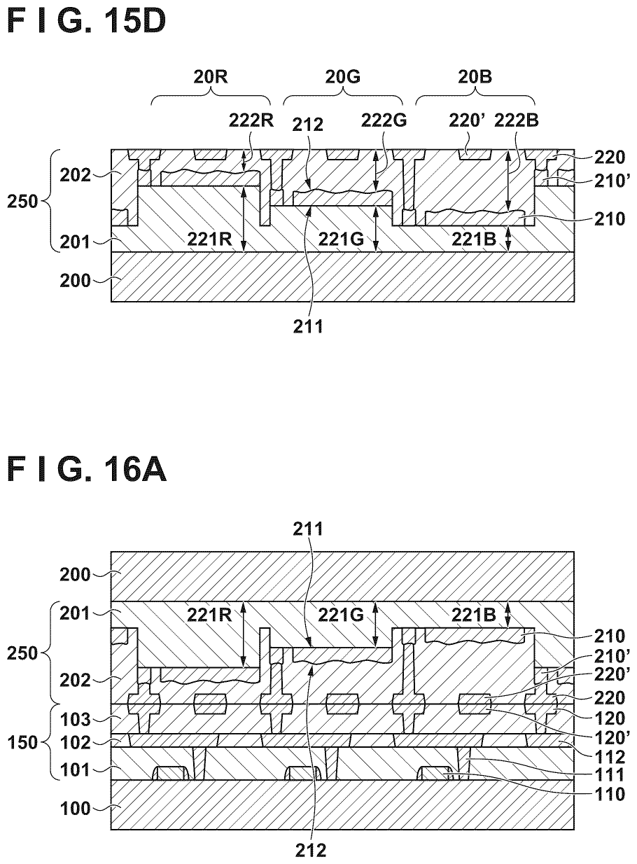

FIGS. 15A to 15D show steps for forming the structure 250 including the reflective layer 210. The steps for forming the structure 250 may be performed in parallel with the steps for forming the structure 150 on the substrate 100 shown in FIGS. 14A to 14D, or may be performed in an appropriate order.

First, as shown in FIG. 15A, the material layer 201′ of the insulating layer 201 is formed on the support substrate 200. A semiconductor such as silicon may be used for the support substrate 200. However, the material used for the support substrate 200 is not limited to a semiconductor such as silicon. Another appropriate material may be used for the support substrate 200 as long as it can support the structure 250 and can be removed in a step to be described later. The material layer 201′ of the insulating layer 201 is formed of a light-transmissive insulator. The material layer 201′ of the insulating layer 201 may have a single layer structure, or a stacked layer structure constituted by a plurality of layers. For the material layer 201′ of the insulating layer 201, for example, silicon oxide, silicon nitride, silicon oxynitride, or the like can be used.

After the material layer 201′ of the insulating layer 201 is formed, as shown in FIG. 15B, the insulating layer 201 is formed using a photolithography step, a dry etching step, and the like. The insulating layer 201 is formed so as to have the thicknesses 221R, 221G, and 221B in the regions 20R, 20G, and 20B where the pixels 400R, 400G, and 400B are to be formed, respectively. That is, the insulating layer 201 is formed by etching the material layer 201′ so as to have different film thicknesses in a portion to form the pixel 400R, a portion to form the pixel 400G, and a portion to form the pixel 400B in the material layer 201′ of the insulating layer 201. For example, when an insulator of the thickness 221R is deposited as the material layer 201′ of the insulating layer 201, only the regions 20G and 20B may be etched using a photolithography step, a dry etching step, and the like to form the insulating layer 201. Since the insulating layer 201 functions as an optical adjustment film as described above, the thickness changes among the regions 20R, 20G, and 20B.

Then, a reflective material is deposited on the insulating layer 201, and the reflective layer 210 and the conductive pattern 210′ are formed using a photolithography step and a dry etching step as shown in FIG. 15C. For the reflective layer 210 and the conductive pattern 210′, for example, a high reflectance material such as aluminum, silver, or platinum, or an alloy containing such material can be used. Particularly, aluminum or an alloy containing aluminum as a main component may be used for the reflective layer 210 and the conductive pattern 210′ since it is easy to increase the resolution. In the contact surface between the reflective layer 210 and the insulating layer 201, for example, a barrier metal layer made of Ti/TiN or the like may be formed.

As shown in FIG. 15C, the unevenness of the surface 211 of the reflective layer 210, which is in contact with the insulating layer 201, is smaller than the unevenness of the surface 212 which is not in contact with the insulating layer 201. As in the above-described embodiment, this is so because the unevenness of the upper surface of the insulating layer 201, on which the reflective layer 210 is formed, has a higher planarity than the surface 212 as the surface after the reflective layer 210 is formed.

In the steps shown in FIGS. 15B and 15C, the material layer 201′ of the insulating layer 201 is etched to appropriate thicknesses for the regions 20R, 20G, and 20B, and then the reflective layer 210 is formed. However, the present invention is not limited to this. An insulating layer having the thickness 221B may be formed, and then an insulating layer may be formed so as to have the thickness 221G in the region other than the region 20B. Further, an insulating layer may be formed to have the thickness 221R in the region other than the regions 20G and 20B, thereby forming the insulating layer 201. In this case, the reflective layer 210 may be formed after the insulating layer 201 is formed, or the reflective layer 210 may be formed for each of the regions 20R, 20G, and 20B at the time when each insulating layer having a predetermined thickness is formed.

Then, by using a deposition step, a planarization step, and the like, the insulating layer 202 is formed to cover the insulating layer 201, the reflective layer 210, and the conductive pattern 210′. Hence, each of the reflective layer 210 and the conductive pattern 210′ is in contact with the insulating layer 202. The insulating layer 202 may have a single layer structure, or a stacked layer structure constituted by a plurality of layers. For the insulating layer 202, for example, silicon oxide, silicon nitride, silicon oxynitride, silicon oxycarbide, silicon oxyfluoride, or the like can be used. Here, the insulating layer 202 is planarized such that the insulating layer 202 formed on the reflective layer 210 has the thicknesses 222R, 222B, and 222G in the regions 20R, 20G, and 20B, respectively.

After the insulating layer 202 is formed, a conductor is embedded in each opening portion provided in the insulating layer 202 using a photolithography step and a dry etching step. Furthermore, by using a planarization step or the like, the bonding pattern 220 and the dummy bonding pattern 220′ are formed as shown in FIG. 15D. Here, the bonding pattern 220 is electrically connected to the reflective layer 210, and the dummy bonding pattern 220′ is insulated without electrical connection. A plurality of the bonding patterns 220 may be arranged for one reflective layer 210. Each of the bonding pattern 220 and the dummy bonding pattern 220′ can be, for example, a copper wiring pattern including a barrier metal layer made of TaCu or the like. The bonding pattern 220 and the dummy bonding pattern 220′ are arranged at an appropriate density.

Through the steps described above, the structure 250 including the reflective layer 210 is formed on the support substrate 200. In the arrangement shown in FIG. 15D, only the reflective layer 210, the bonding pattern 220, and the dummy bonding pattern 220′ are arranged in the structure 250. However, the present invention is not limited to this, and one or more wiring layers including a wiring pattern may be formed between the reflective layer 210 and the bonding pattern 220 (dummy bonding pattern 220′).

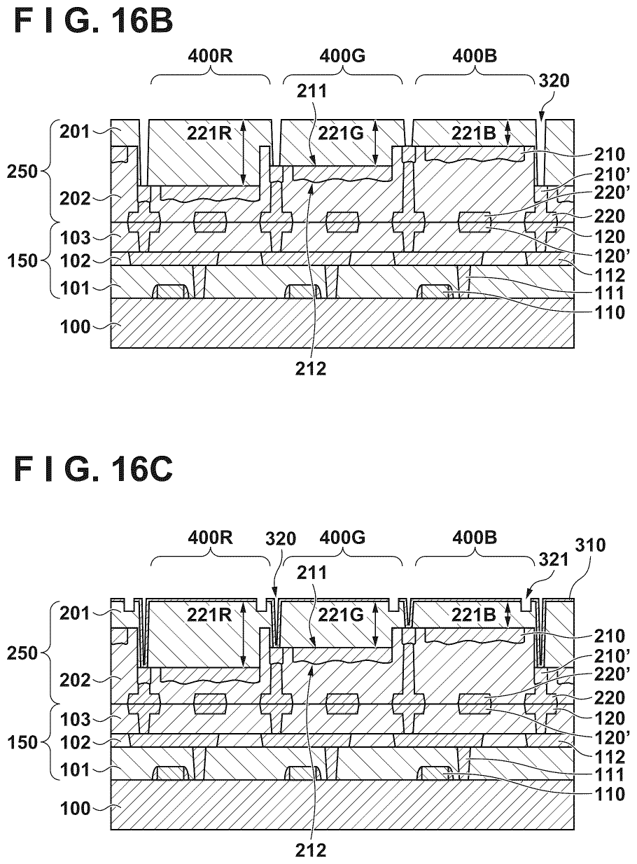

Then, a bonding step of the structure 150 formed on the substrate 100 and the structure 250 formed on the support substrate 200 and including the reflective layer 210 is performed as shown in FIG. 16A. In a step shown in FIG. 16A, the insulating layer 103 (bonding layer) forming the surface of the structure 150 and the insulating layer 202 (bonding layer) forming the surface of the structure 250 are bonded. As shown in FIG. 16A, for example, the structure 250 is placed on the structure 150, and heat treatment or the like is performed to bond them. At this time, the bonding pattern 120 of the structure 150 and the bonding pattern 220 of the structure 250 are bonded to each other. Similarly, the dummy bonding pattern 120′ of the structure 150 and the dummy bonding pattern 220′ of the structure 250 are bonded to each other. By bonding the bonding pattern 120 and the bonding pattern 220 to each other, the transistor 110 for controlling driving of the pixel 400 and the reflective layer 210 are electrically connected.

Then, a step of removing the support substrate 200 is performed. The support substrate 200 is removed at least partially, more specifically, at least in the region where the pixel 400 is arranged, to expose the insulating layer 201. The support substrate 200 may entirely be removed. For example, a film thinning step is used to remove the support substrate 200. Examples of the film thinning step for removing the support substrate 200 are a back grinding step, a chemical mechanical polishing step, and an etching step.

After the insulating layer 201 is exposed, as shown in FIG. 16B, the opening portion 320 is formed to extend through the insulating layer 210 on the conductive pattern 210′. The opening portion 320 is formed using a photolithography step and a dry etching step. As shown in FIG. 16B, the depth of the opening portion 320 is equal to the corresponding one of the thicknesses 221R, 221G, and 221B of the insulating layer 201. Thus, the conductive pattern 210′ is exposed.

After the opening portion 320 is formed, the electrode 310 is formed on the insulating layer 201. The electrode 310 is formed of a transparent material. For example, indium tin oxide, indium zinc oxide, or the like can be used for the electrode 310. The electrode 310 is electrically connected to the conductive pattern 210′ via the opening portion 320. As shown in FIG. 7, the conductive plug 312 may be embedded in the opening portion 320, and the electrode 310 may be formed thereon. After the electrode 310 is formed, as shown in FIG. 16C, the opening portion 321 is formed using a photolithography step and a dry etching step to insulate the electrodes 310 of the adjacent pixels 400 from each other. The subsequent steps may be similar to the steps from FIG. 6A, and a description thereof will be omitted.

In the arrangement shown in FIG. 13, it is possible to form a plurality of the opening portions 320 each connecting the electrode 310 and the conductive pattern 210′. Therefore, this has an effect of suppressing a conductive failure between the transistor 110 and the electrode 310.

Also in this embodiment, the unevenness (surface roughness) of the surface 211 of the reflective layer 210, which is in contact with the insulating layer 201, is smaller than the unevenness (surface roughness) of the surface 212 which is not in contact with the insulating layer 201. This can improve the reflectance at the reflective layer 210, thereby improving the light emission efficiency of the light emitting device 500.

The above-described embodiments may be used in combination, as appropriate. For example, the conductive pattern 210′ may be combined with the arrangement as shown in FIG. 9 in which the distance between the reflective layer 210 and the substrate 100 is the same among the pixels 400.

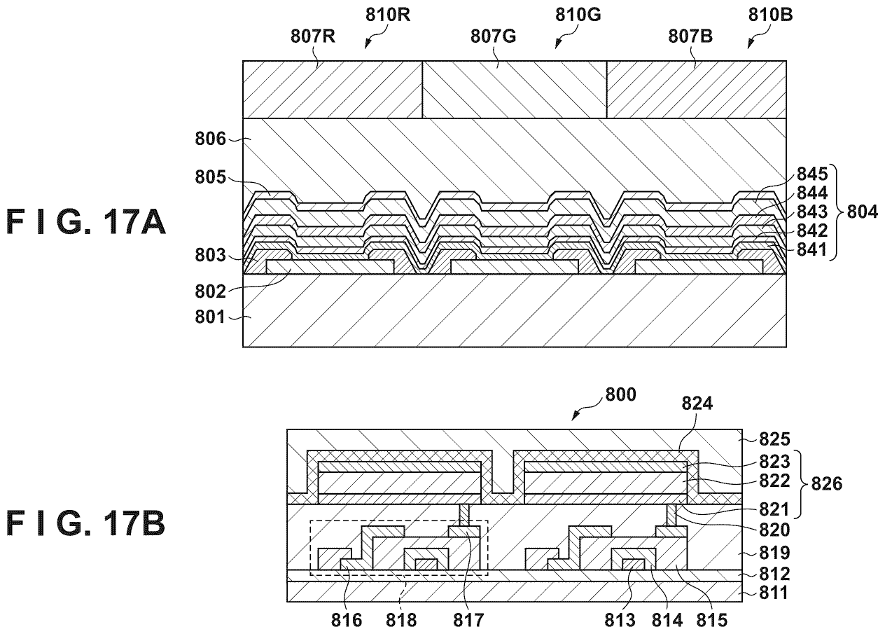

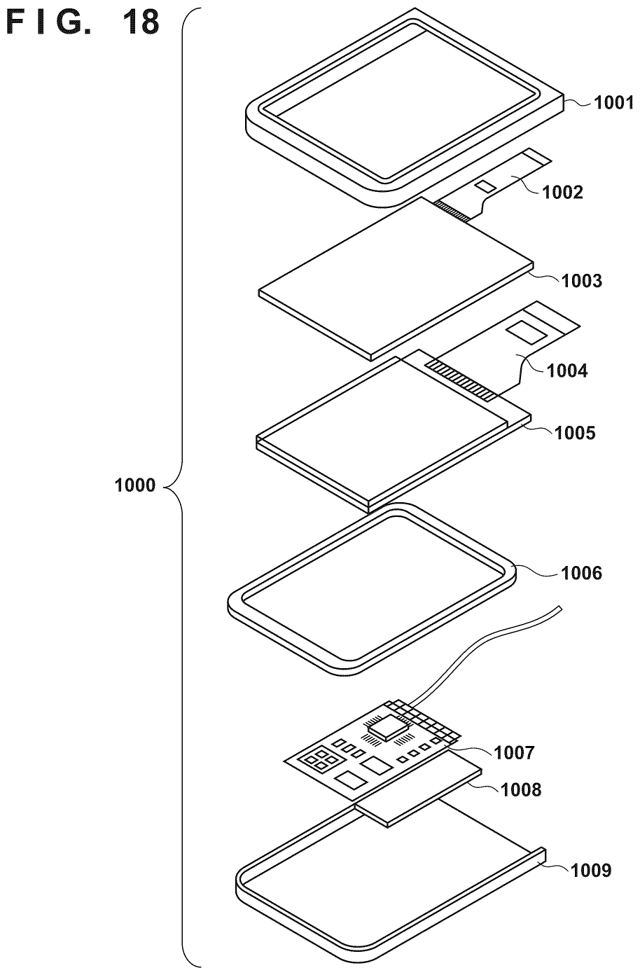

Here, with reference to FIGS. 17A to 24B, application examples in which the light emitting device 500 according to this embodiment is applied to a display device, a photoelectric conversion device, an electronic apparatus, an illumination device, a moving body, and a wearable device will be described. The description will be given assuming that, for example, an organic light emitting element (OLED) such as an organic EL element using an organic light emitting material is arranged in the pixel 400 of the light emitting device 500. Details of each component arranged in the pixel 400 of the light emitting device 500 described above will be described first, and the application examples will be described after that.

The organic light emitting element according to an embodiment of the present disclosure includes a first electrode, a second electrode, and an organic compound layer arranged between these electrodes. One of the first electrode and the second electrode is an anode, and the other is a cathode. In the organic light emitting element according to this embodiment, the organic compound layer may be either a single layer or a stacked body formed by a plurality of layers as long as it includes a light emitting layer. Here, if the organic compound layer is a stacked body formed from a plurality of layers, the organic compound layer may include a hole injection layer, a hole transport layer, an electron blocking layer, a hole/exciton blocking layer, an electron transport layer, an electron injection layer, and the like in addition to the light emitting layer. The light emitting layer may be a single layer or a stacked body formed from a plurality of layers. If the light emitting layer includes a plurality of layers, a charge generation layer may be arranged between the light emitting layers. The charge generation layer may be made of a compound having the LUMO lower than that of the hole transport layer, and the LUMO of the charge generation layer may be lower than the HOMO of the hole transport layer. Here, the molecular orbital energy of the organic compound layer may be the molecular orbital energy of the organic compound with the largest weight ratio in the organic compound layer.

The description is given here assuming that the closer the HOMO and LUMO are to the vacuum level, the “higher” they are. When the LUMO of the charge generation layer is lower than the HOMO of the hole transport layer, the LUMO of the charge generation layer is closer to the vacuum level than the HOMO of the hole transport layer.

The HOMO and LUMO in this specification can be calculated using molecular orbital calculation. The molecular orbital calculation is executed by a Density Functional Theory (DFT) or the like. A functional may be calculated using B3LYP, and a basic function may be calculated using 6-31G*. Note that molecular orbital calculation can be executed using, for example, Gaussian 09 (Gaussian 09, Revision C.01, M. J. Frisch, G. W. Trucks, H. B. Schlegel, G. E. Scuseria, M. A. Robb, J. R. Cheeseman, G. Scalmani, V. Barone, B. Mennucci, G. A. Petersson, H. Nakatsuji, M. Caricato, X. Li, H. P. Hratchian, A. F. Izmaylov, J. Bloino, G. Zheng, J. L. Sonnenberg, M. Hada, M. Ehara, K. Toyota, R. Fukuda, J. Hasegawa, M. Ishida, T. Nakajima, Y. Honda, O. Kitao, H. Nakai, T. Vreven, J. A. Montgomery Jr., J. E. Peralta, F. Ogliaro, M. Bearpark, J. J. Heyd, E. Brothers, K. N. Kudin, V. N. Staroverov, T. Keith, R. Kobayashi, J. Normand, K. Raghavachari, A. Rendell, J. C. Burant, S. S. Iyengar, J. Tomasi, M. Cossi, N. Rega, J. M. Millam, M. Klene, J. E. Knox, J. B. Cross, V. Bakken, C. Adamo, J. Jaramillo, R. Gomperts, R. E. Stratmann, O. Yazyev, A. J. Austin, R. Cammi, C. Pomelli, J. W. Ochterski, R. L. Martin, K. Morokuma, V. G. Zakrzewski, G. A. Voth, P. Salvador, J. J. Dannenberg, S. Dapprich, A. D. Daniels, O. Farkas, J. B. Foresman, J. V. Ortiz, J. Cioslowski, and D. J. Fox, Gaussian, Inc., Wallingford CT, 2010.)

The HOMO and LUMO in this specification can be calculated using the ionization potential and band gap. The HOMO can be estimated by measuring the ionization potential. The ionization potential can be measured by dissolving the compound to be measured in a solvent such as toluene and using a measuring device such as AC-3. The band gap can be measured by dissolving the compound to be measured in a solvent such as toluene and irradiating it with excitation light. The band gap can be measured by measuring the absorption edge of the excitation light. Alternatively, the band gap can be measured by depositing the compound to be measured on a substrate such as glass, and exposing the deposited film to excitation light. The band gap can be measured by measuring the absorption edge of the absorption spectrum at which the deposited film absorbs excitation light.

The LUMO can be calculated using the band gap and ionization potential value. The LUMO can be estimated by subtracting the ionization potential value from the band gap.

The LUMO can also be estimated from the reduction potential. For example, the one-electron reduction potential is estimated using cyclic voltammetry (CV) measurement. The CV measurement can be performed, for example, in a DMF solution of 0.1 M tetrabutylammonium perchlorate using a reference electrode of Ag/Ag⁺, a counter electrode of Pt, and a working electrode of glassy carbon. The LUMO can be estimated by adding −4.8 eV to the difference between the reduction potential of the obtained compound and that of ferrocene.

A conventionally known low molecular and high molecular hole injection compound or hole transport compound, a compound serving as a host, a light emitting compound, an electron injection compound or electron transport compound, or the like can be used together as needed. Examples of these compounds will be described below.

As a hole injection/transport material, a material that has a high hole mobility such that hole injection from the anode is facilitated, and injected holes can be transported to the light emitting layer can suitably be used. Also, a material having a high glass transition point temperature can suitably be used to reduce degradation of film quality such as crystallization in the organic light emitting element. Examples of low molecular and high molecular materials having hole injection/transport performance are a triarylamine derivative, an arylcarbazole derivative, a phenylenediamine derivative, a stilbene derivative, a phthalocyanine derivative, a porphyrin derivative, a poly(vinyl carbazole), a poly(thiophene), and other conductive polymers. The above-described hole injection/transport material can suitably be used for the electron blocking layer as well. Detailed examples of compounds used as the hole injection/transport material will be shown below. The material is not limited to these.

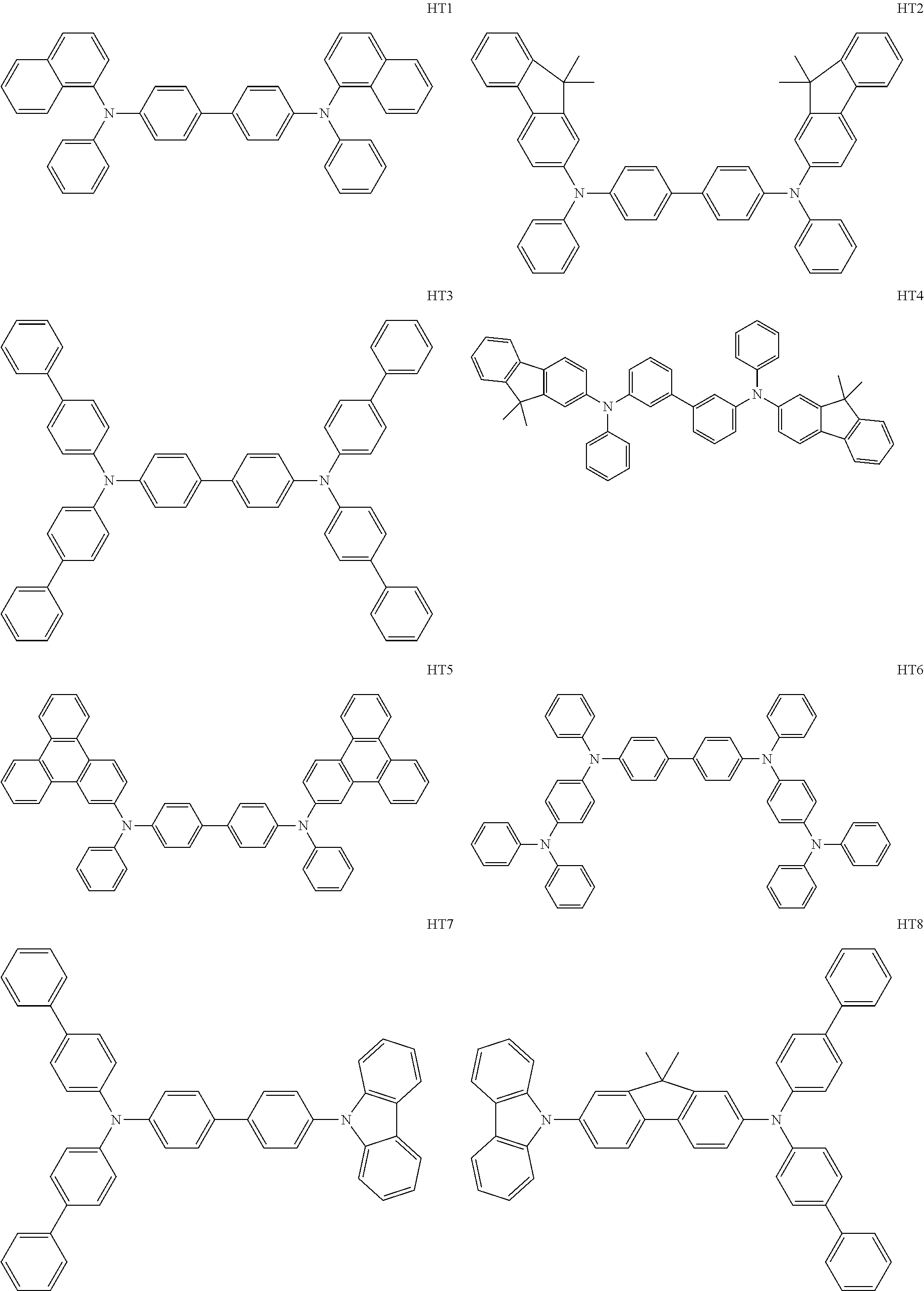

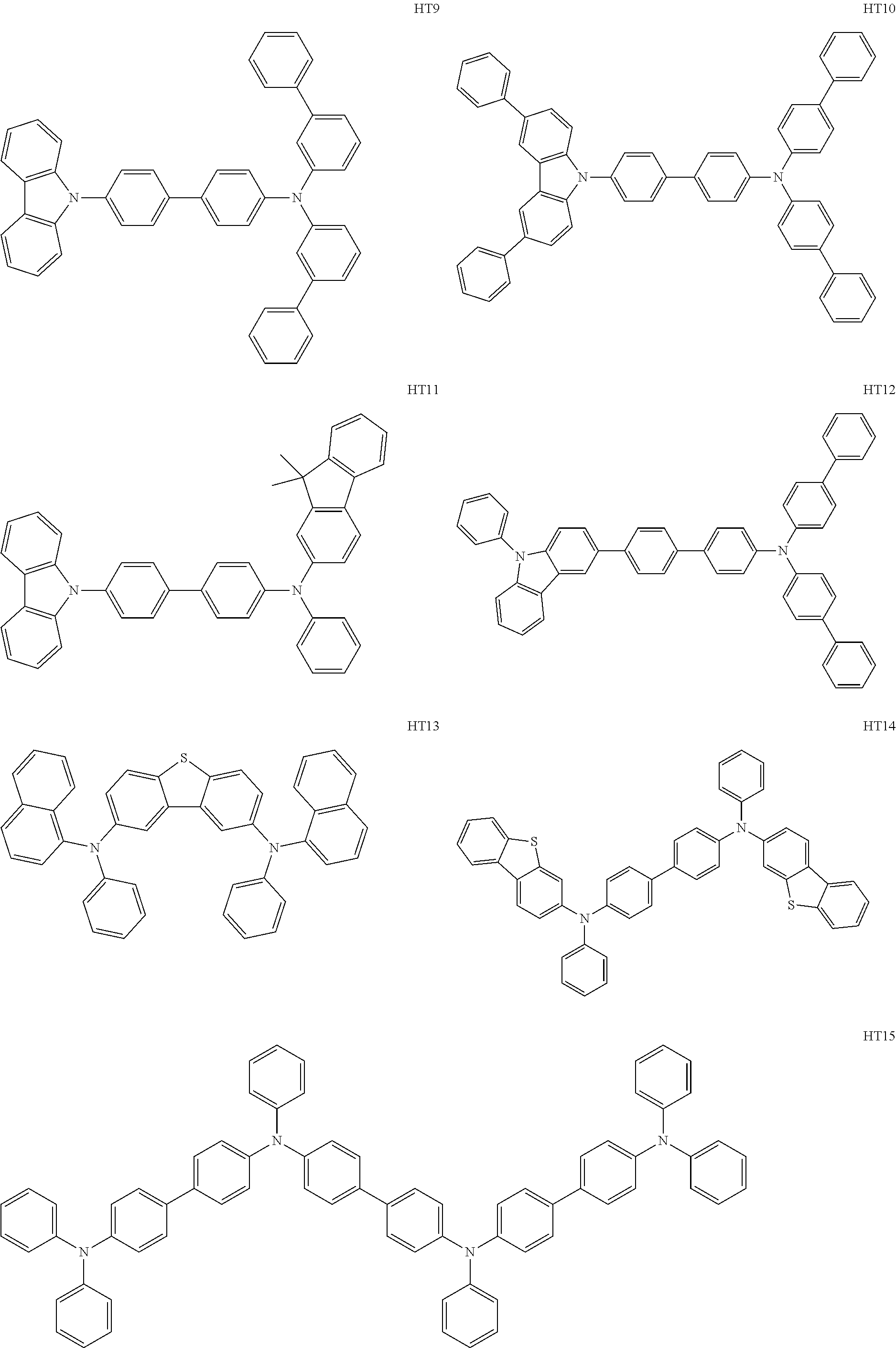

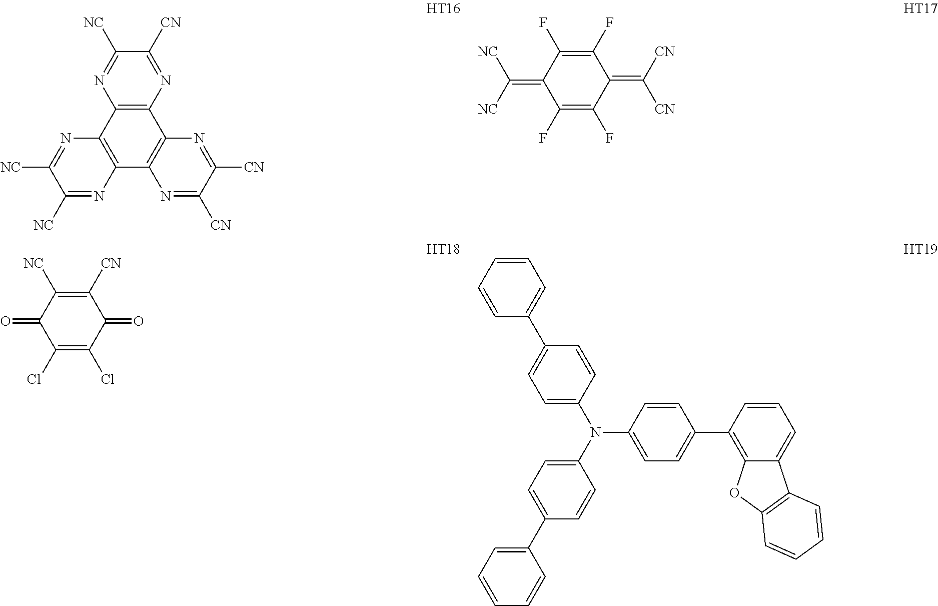

In the hole transport materials, HT16 to HT18 can decrease the driving voltage when used in a layer in contact with the anode. HT16 is widely used in an organic light emitting element. HT2, HT3, HT4, HT5, HT6, HT10, and HT12 can be used in an organic compound layer adjacent to HT16. A plurality of materials may be used in one organic compound layer.

Examples of the light emitting material mainly concerning the light emitting function are condensed-ring compounds (for example, a fluorene derivative, a naphthalene derivative, a pyrene derivative, a perylene derivative, a tetracene derivative, an anthracene derivative, and rubrene), a quinacridone derivative, a coumarin derivative, a stilbene derivative, an organic aluminum complex such as tris(8-quinolinolato)aluminum, an iridium complex, a platinum complex, a rhenium complex, a copper complex, a europium complex, a ruthenium complex, and polymer derivatives such as a poly(phenylenevinylene) derivative, a poly(fluorene) derivative, and a poly(phenylene) derivative.

Detailed examples of compounds used as the light emitting material will be shown below. The material is not limited to these.

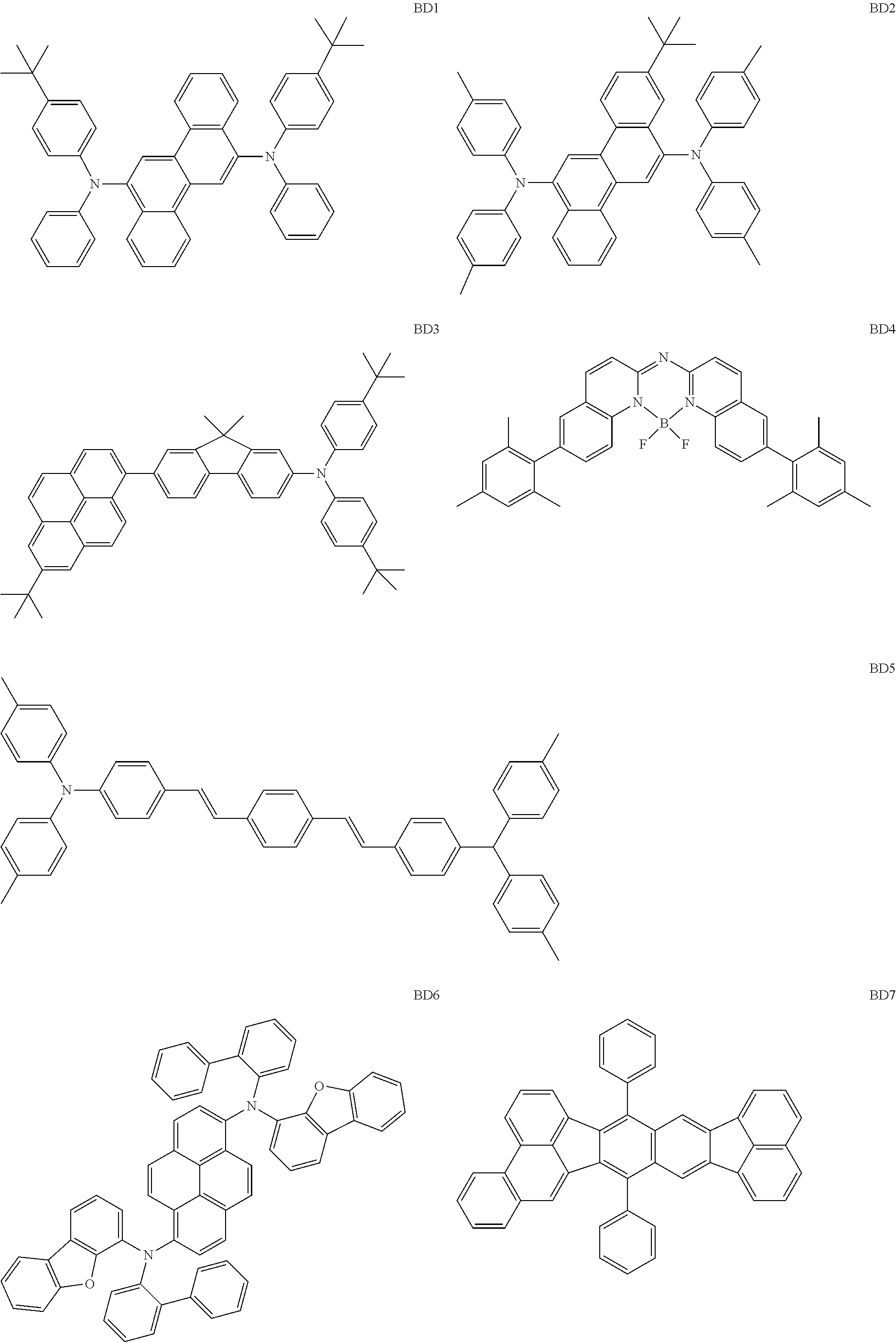

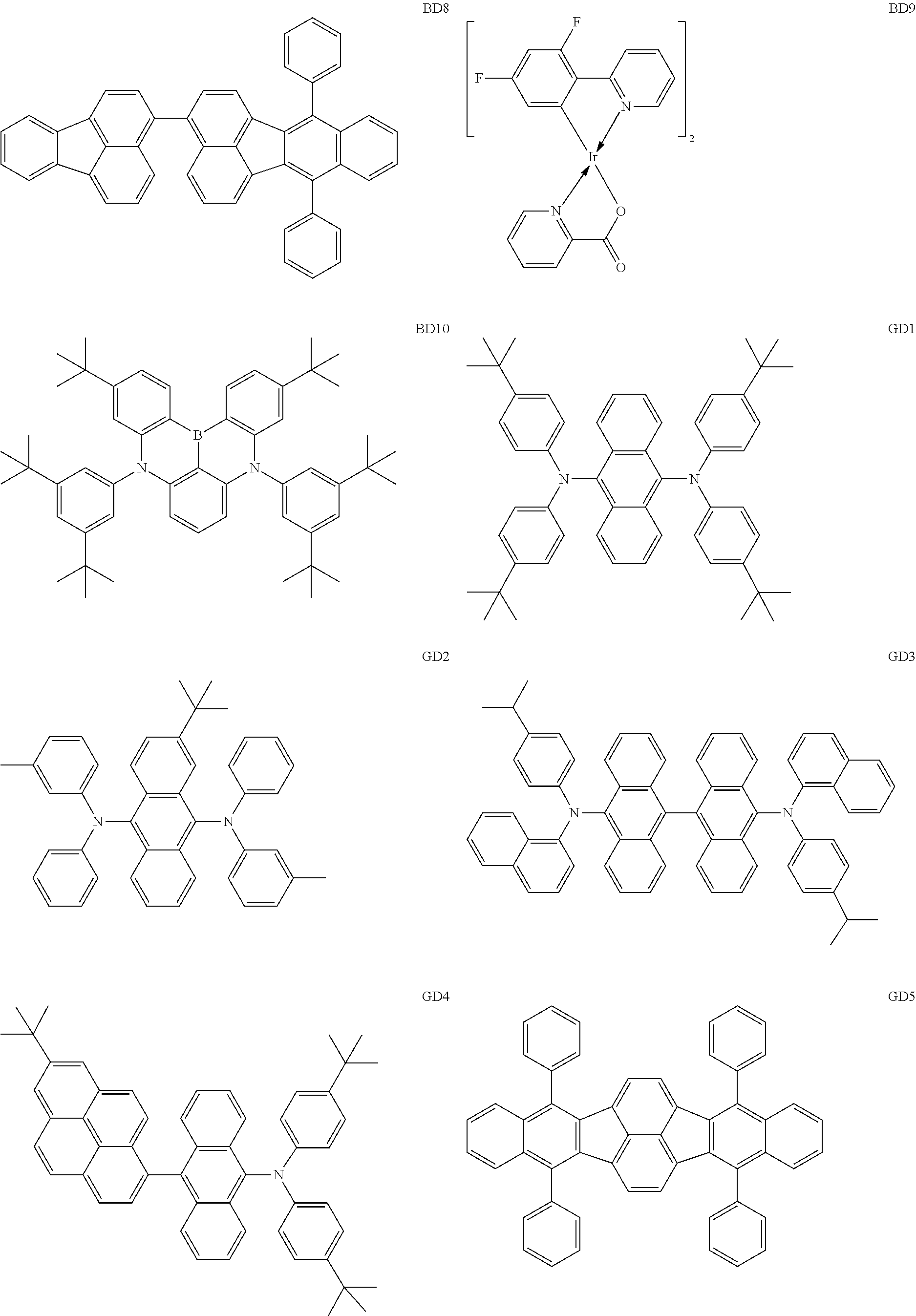

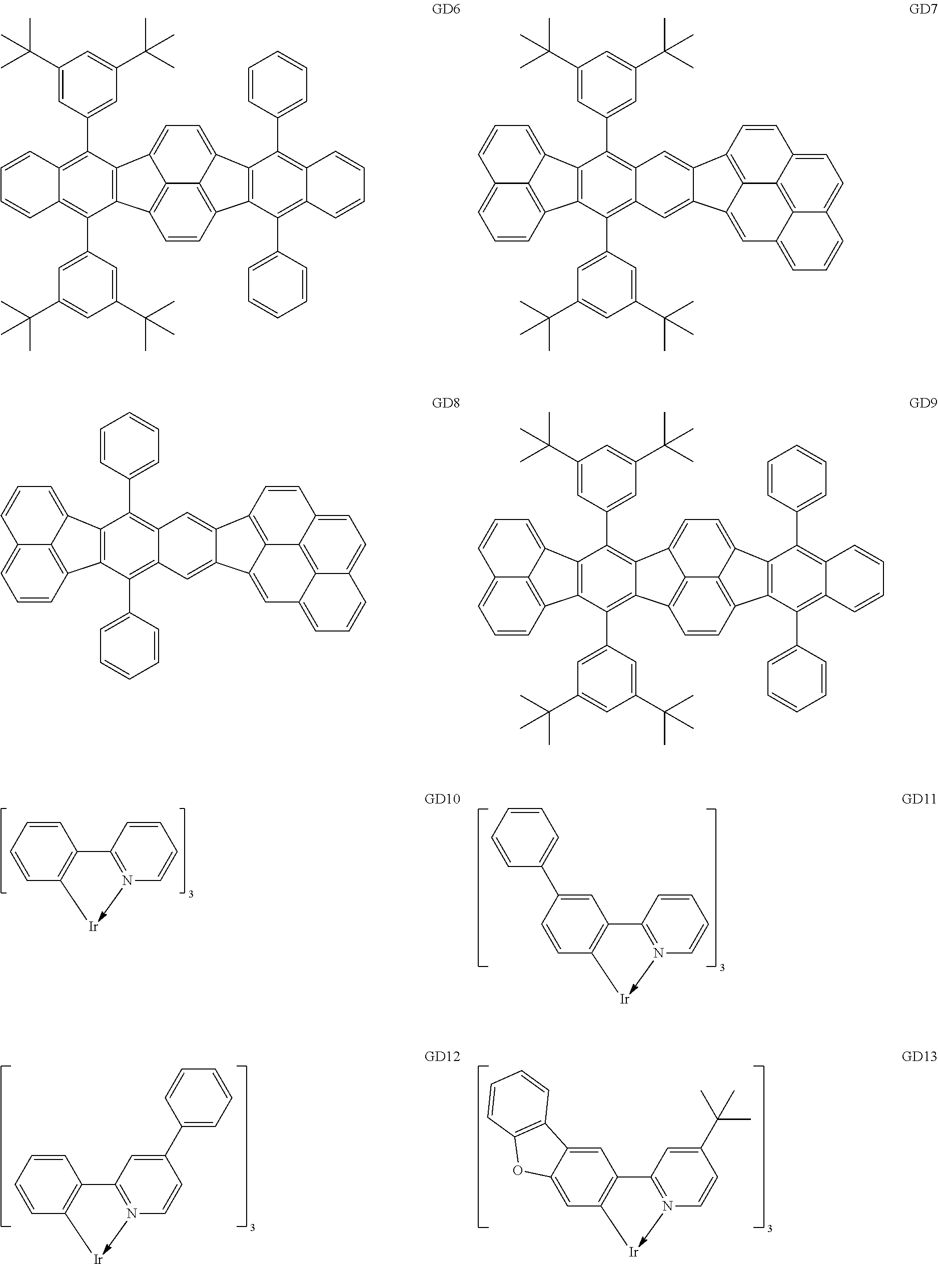

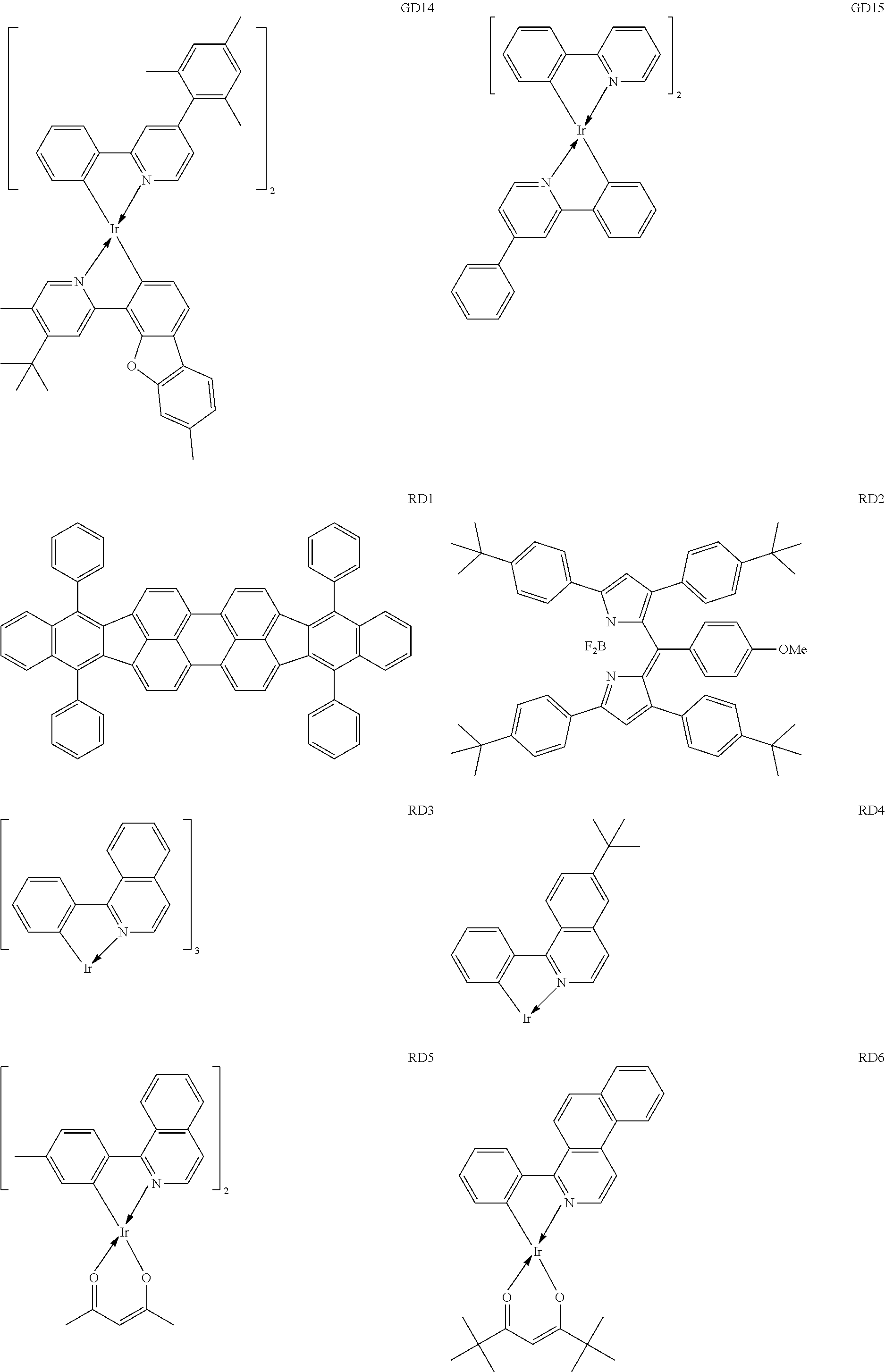

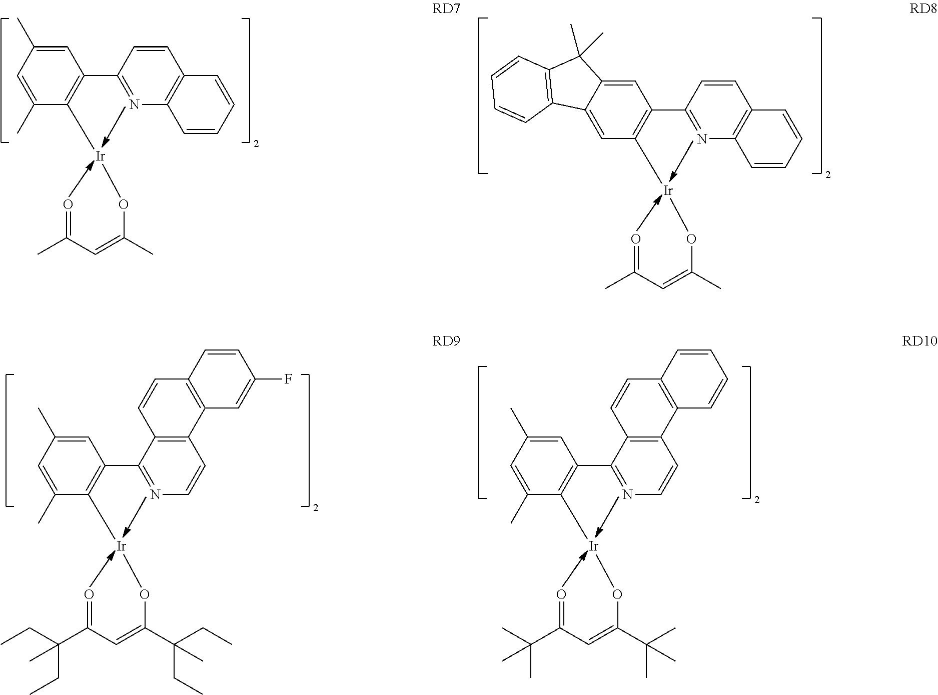

If the light emitting material is a hydrocarbon compound, this is suitable because it is possible to reduce lowering of light emission efficiency caused by exciplex formation or lowering of color purity due to a change of the light emission spectrum of the light emitting material caused by exciplex formation.

The hydrocarbon compound is a compound made of only carbon and hydrogen, and includes BD7, BD8, GD5 to GD9, and RD1 in the compounds exemplified above.

If the light emitting material is a condensed polycyclic compound including a 5-membered ring, this is suitable because oxidation hardly occurs because of a high ionization potential, and a long-life element with high durability can be obtained. This includes BD7, BD8, GD5 to GD9, and RD1 in the compounds exemplified above.

Examples of the light emitting layer host or the light emission assist material contained in the light emitting layer are an aromatic hydrocarbon compound or its derivative, a carbazole derivative, a dibenzofuran derivative, a dibenzothiophene derivative, an organic aluminum complex such as tris(8-quinolinolato)aluminum, and an organic beryllium complex.

Detailed examples of compounds used as the light emitting layer host or the light emission assist material contained in the light emitting layer will be shown below. The material is not limited to these.

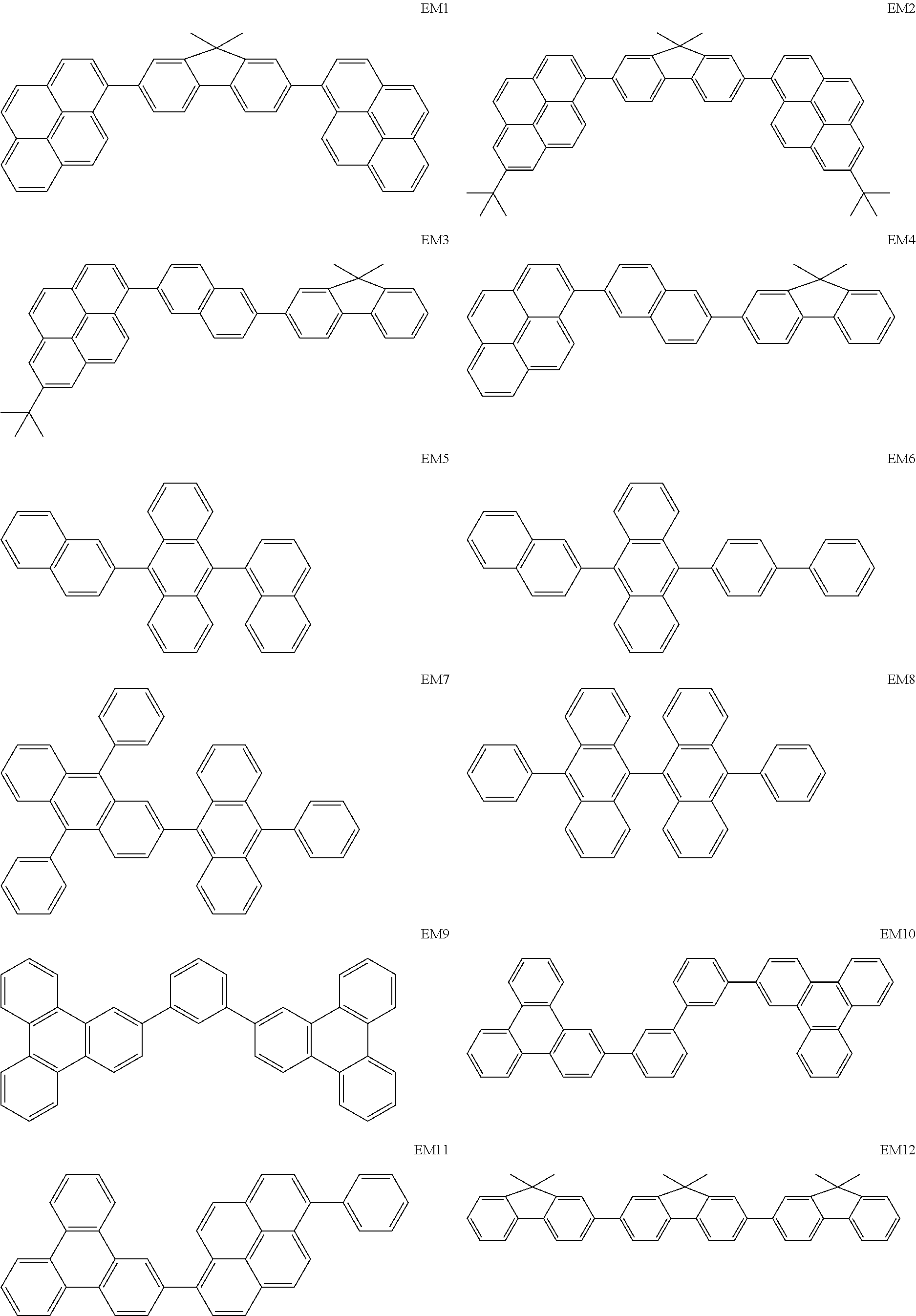

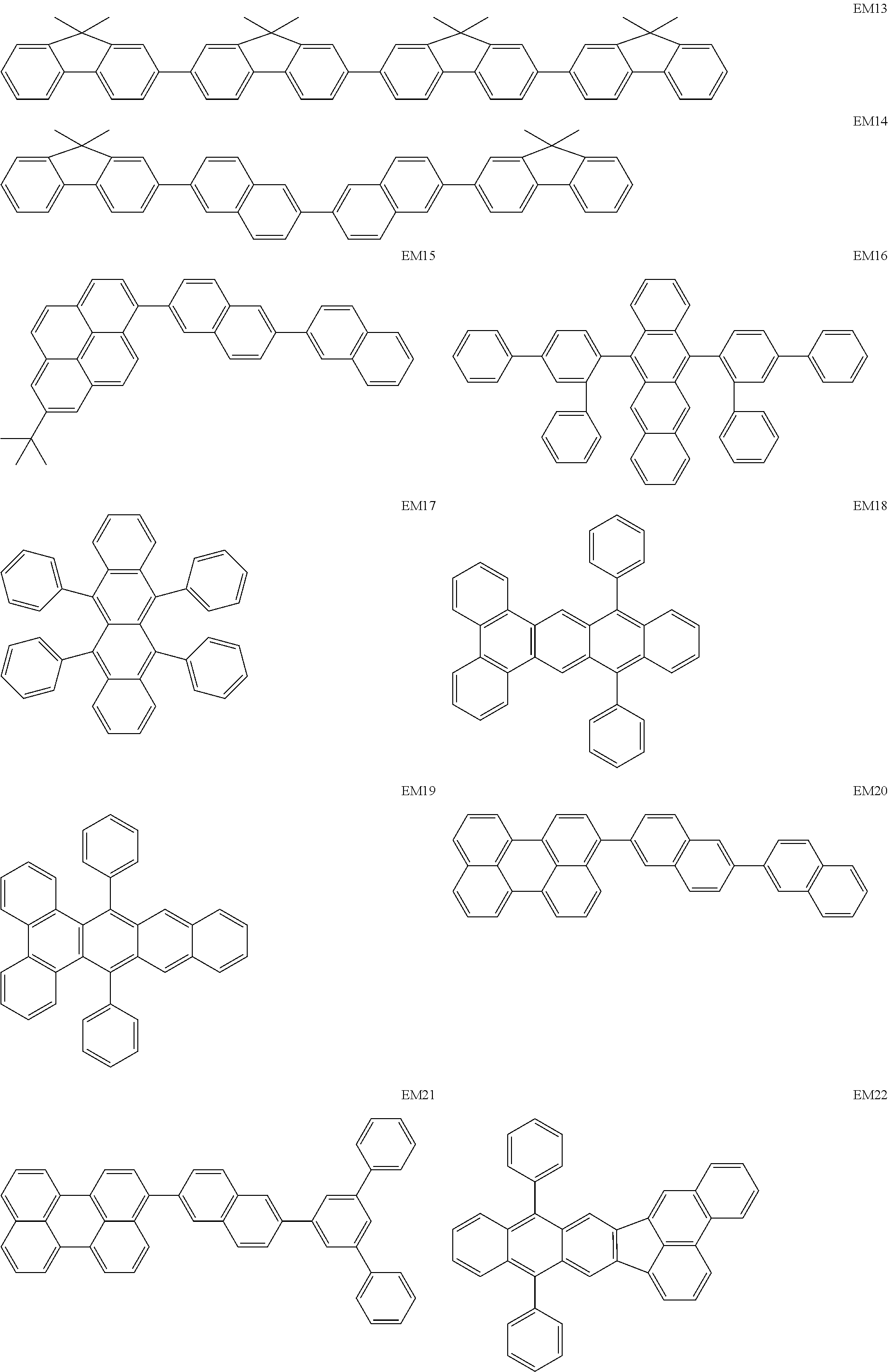

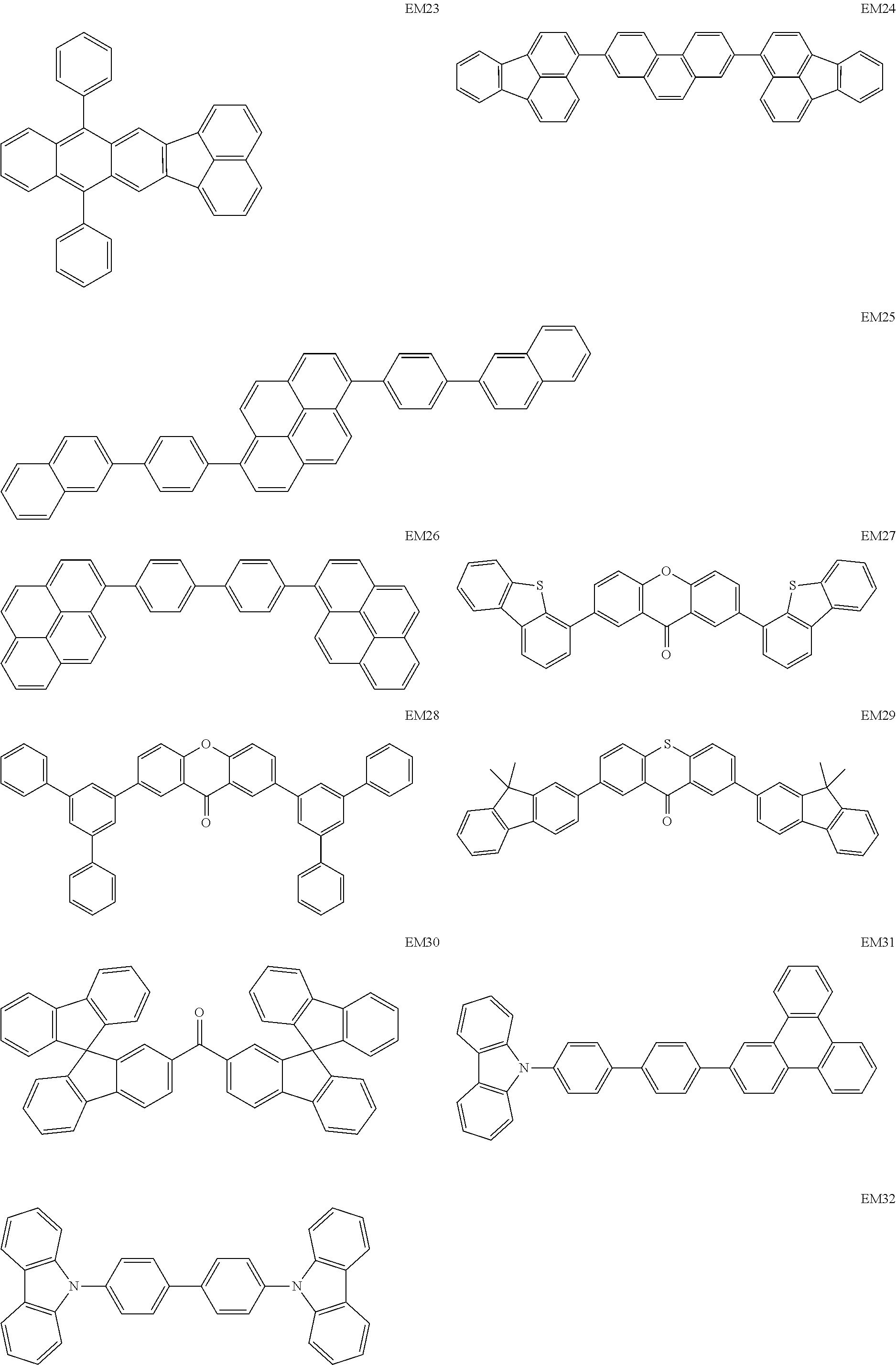

The host material may be a hydrocarbon compound. The hydrocarbon compound is a compound made of only carbon and hydrogen, and includes EM1 to EM12 and EM16 to EM27 in the compounds exemplified above. As the host material, a material that has, in a single bond that bonds an aryl group unit in its structure, no carbon-heteroatom bonds, like F3 in compound 1, is suitable from the viewpoint of stability.

The electron transport material can arbitrarily be selected from materials capable of transporting electrons injected from the cathode to the light emitting layer, and is selected in consideration of balance to the hole mobility of the hole transport material. Examples of the material having electron transport performance are an oxadiazole derivative, an oxazole derivative, a pyrazine derivative, a triazole derivative, a triazine derivative, a quinoline derivative, a quinoxaline derivative, a phenanthroline derivative, an organic aluminum complex, and condensed-ring compounds (for example, a fluorene derivative, a naphthalene derivative, a chrysene derivative, and an anthracene derivative). The above-described electron transport material is suitably used for the hole blocking layer as well.

Detailed examples of compounds used as the electron transport material will be shown below. The material is not limited to these.

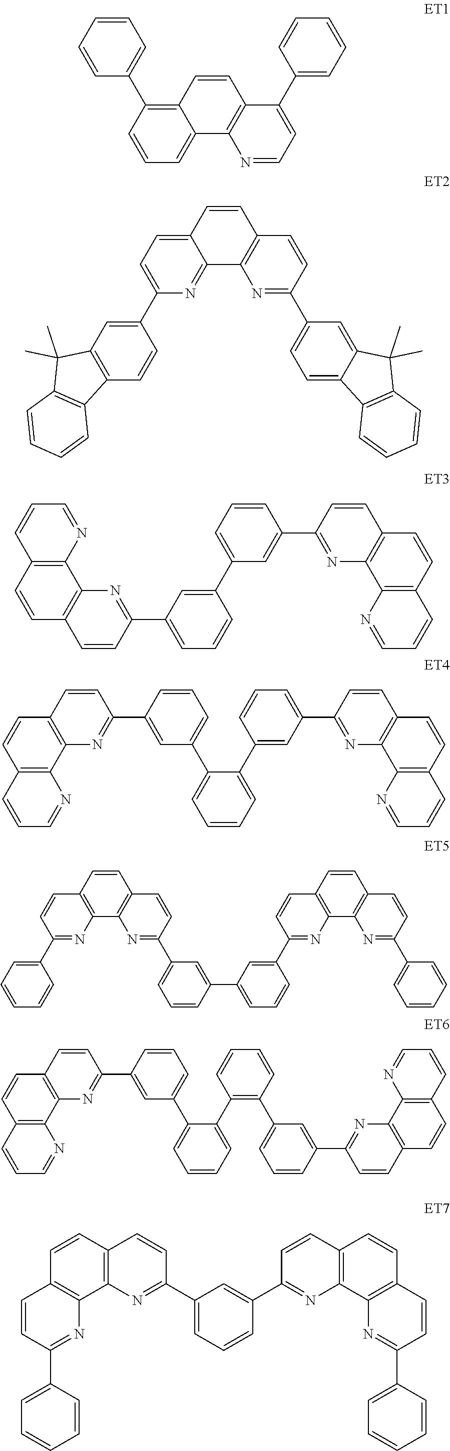

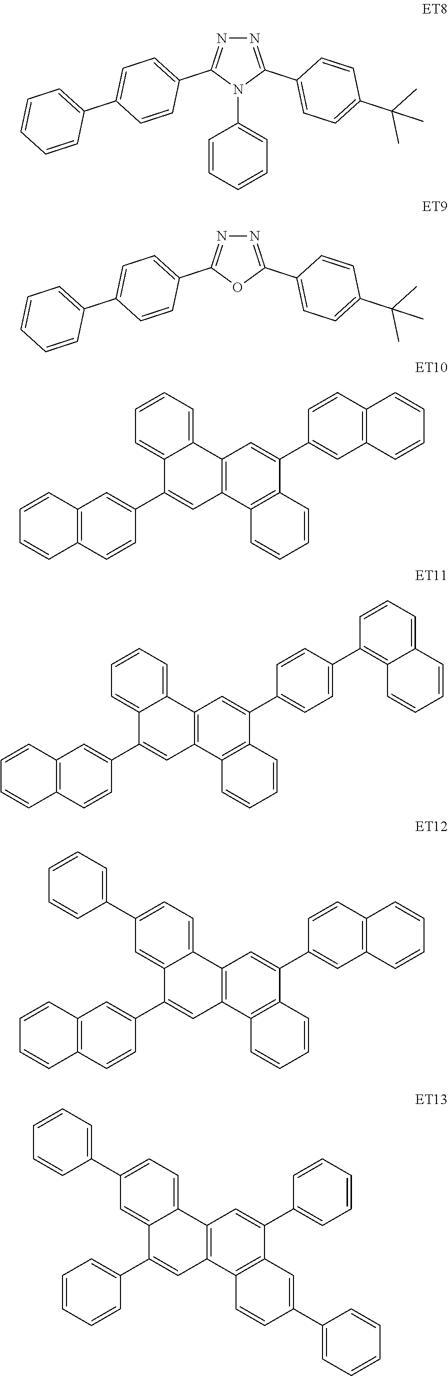

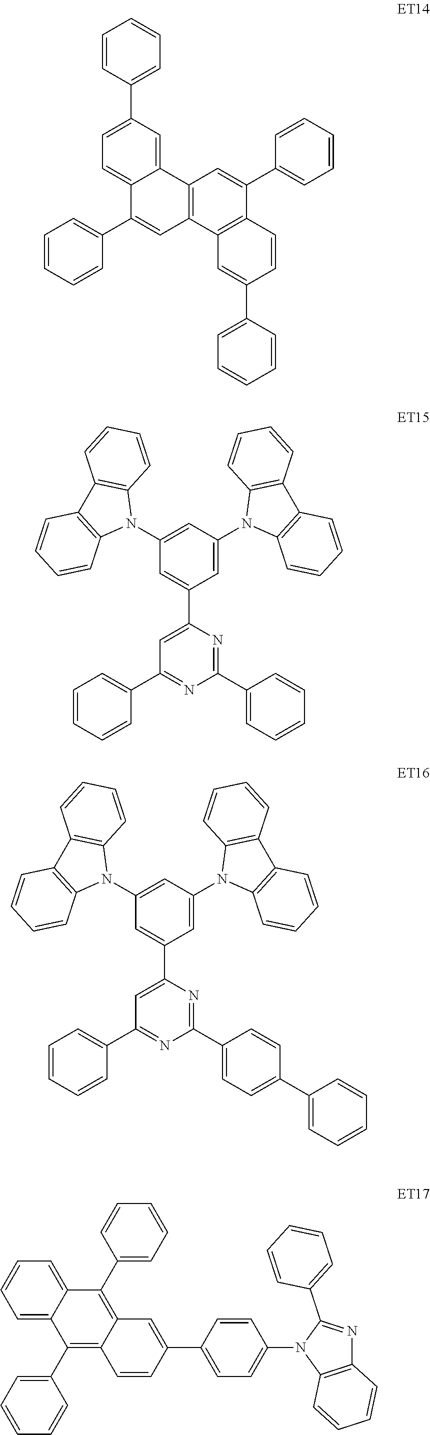

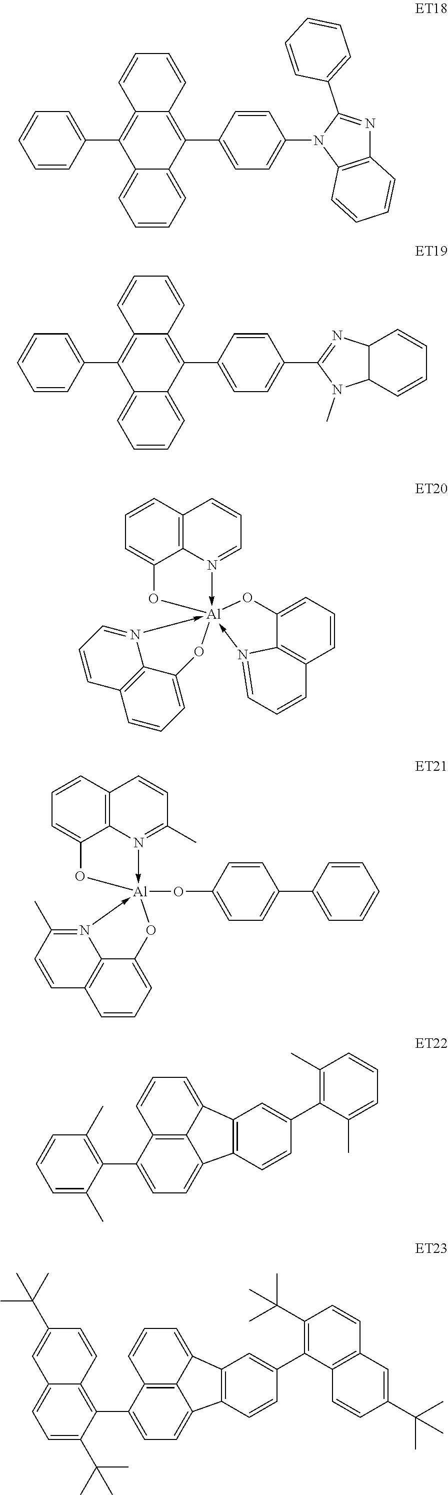

The electron injection material can arbitrarily be selected from materials capable of facilitating electron injection from the cathode, and is selected in consideration of balance to hole injection. The organic compound includes an n-type dopant and a reducible dopant. Examples are a compound containing an alkali metal such as lithium fluoride, a lithium complex such as a lithium-quinolinol complex, a benzo-imidazolidene derivative, an imidazolidene derivative, a fulvalene derivative, and an acridine derivative.

The electron injection material can also be used together with the above-described electron transport material.

### Configuration of Organic Light Emitting Element

The organic light emitting element is provided by forming an insulating layer, a first electrode, an organic compound layer, and a second electrode on a substrate. A protection layer, a color filter, a microlens, and the like may be provided on a cathode. If a color filter is provided, a planarizing layer may be provided between the protection layer and the color filter. The planarizing layer can be formed using acrylic resin or the like. The same applies to a case where a planarizing layer is provided between the color filter and the microlens.

### Substrate

Quartz, glass, a silicon wafer, a resin, a metal, or the like may be used as a substrate. Furthermore, a switching element such as a transistor, a wiring pattern, and the like may be provided on the substrate, and an insulating layer may be provided thereon. The insulating layer may be made of any material as long as a contact hole can be formed so that the wiring pattern can be formed between the first electrode and the substrate and insulation from the unconnected wiring pattern can be ensured. For example, a resin such as polyimide, silicon oxide, silicon nitride, or the like may be used for the insulating layer.

### Electrode

A pair of electrodes can be used as the electrodes. The pair of electrodes can be an anode and a cathode. If an electric field is applied in the direction in which the organic light emitting element emits light, the electrode having a high potential is the anode, and the other is the cathode. It can also be said that the electrode that supplies holes to the light emitting layer is the anode and the electrode that supplies electrons is the cathode.

As the constituent material of the anode, a material having a large work function may be selected. For example, a metal such as gold, platinum, silver, copper, nickel, palladium, cobalt, selenium, vanadium, or tungsten, a mixture containing some of them, an alloy obtained by combining some of them, or a metal oxide such as tin oxide, zinc oxide, indium oxide, indium tin oxide (ITO), or zinc indium oxide can be used. Furthermore, a conductive polymer such as polyaniline, polypyrrole, or polythiophene can also be used as the constituent material of the anode.

One of these electrode materials may be used singly, or two or more of them may be used in combination. The anode may be formed by a single layer or a plurality of layers.

If the electrode is used as a reflective electrode, for example, chromium, aluminum, silver, titanium, tungsten, molybdenum, an alloy thereof, a stacked layer thereof, or the like can be used. The above materials can function as a reflective film having no role as an electrode. If a transparent electrode is used as the electrode, an oxide transparent conductive layer made of indium tin oxide (ITO), indium zinc oxide, or the like can be used, but the present invention is not limited thereto. A photolithography technique can be used to form the electrode.

On the other hand, as the constituent material of the cathode, a material having a small work function may be selected. Examples of the material include an alkali metal such as lithium, an alkaline earth metal such as calcium, a metal such as aluminum, titanium, manganese, silver, lead, or chromium, and a mixture containing some of them. Alternatively, an alloy obtained by combining these metals can also be used. For example, a magnesium-silver alloy, an aluminum-lithium alloy, an aluminum-magnesium alloy, a silver-copper alloy, a zinc-silver alloy, or the like can be used. A metal oxide such as indium tin oxide (ITO) can also be used. One of these electrode materials may be used singly, or two or more of them may be used in combination. The cathode may have a single-layer structure or a multilayer structure. Silver may be used as the cathode. To suppress aggregation of silver, a silver alloy may be used. The ratio of the alloy is not limited as long as aggregation of silver can be suppressed. For example, the ratio between silver and another metal may be 1:1, 3:1, or the like.

The cathode may be a top emission element using an oxide conductive layer made of ITO or the like, or may be a bottom emission element using a reflective electrode made of aluminum (Al) or the like, and is not particularly limited. The method of forming the cathode is not particularly limited, but if direct current sputtering or alternating current sputtering is used, the good coverage is achieved for the film to be formed, and the resistance of the cathode can be lowered.

### Pixel Isolation Layer

A pixel isolation layer may be formed by a so-called silicon oxide, such as silicon nitride (SiN), silicon oxynitride (SiON), or silicon oxide (SiO), formed using a Chemical Vapor Deposition (CVD) method. To increase the resistance in the in-plane direction of the organic compound layer, the organic compound layer, especially the hole transport layer may be thinly deposited on the side wall of the pixel isolation layer. More specifically, the organic compound layer can be deposited so as to have a thin film thickness on the side wall by increasing the taper angle of the side wall of the pixel isolation layer or the film thickness of the pixel isolation layer to increase vignetting during vapor deposition.

On the other hand, the taper angle of the side wall of the pixel isolation layer or the film thickness of the pixel isolation layer can be adjusted to the extent that no space is formed in the protection layer formed on the pixel isolation layer. Since no space is formed in the protection layer, it is possible to reduce generation of defects in the protection layer. Since generation of defects in the protection layer is reduced, a decrease in reliability caused by generation of a dark spot or occurrence of a conductive failure of the second electrode can be reduced.

According to this embodiment, even if the taper angle of the side wall of the pixel isolation layer is not acute, it is possible to effectively suppress leakage of charges to an adjacent pixel. As a result of this consideration, it has been found that the taper angle of 60° (inclusive) to 90° (inclusive) can sufficiently reduce the occurrence of defects. The film thickness of the pixel isolation layer may be 10 nm (inclusive) to 150 nm (inclusive). A similar effect can be obtained in a configuration including only pixel electrodes without the pixel isolation layer. However, in this case, the film thickness of the pixel electrode is set to be equal to or smaller than half the film thickness of the organic layer or the end portion of the pixel electrode is formed to have a forward tapered shape of less than 60°. With this, short circuit of the organic light emitting element can be reduced.

Furthermore, in a case where the first electrode is the cathode and the second electrode is the anode, a high color gamut and low-voltage driving can be achieved by forming the electron transport material and charge transport layer and forming the light emitting layer on the charge transport layer.

### Organic Compound Layer

The organic compound layer may be formed by a single layer or a plurality of layers. If the organic compound layer includes a plurality of layers, the layers can be called a hole injection layer, a hole transport layer, an electron blocking layer, a light emitting layer, a hole blocking layer, an electron transport layer, and an electron injection layer in accordance with the functions of the layers. The organic compound layer is mainly formed from an organic compound but may contain inorganic atoms and an inorganic compound. For example, the organic compound layer may contain copper, lithium, magnesium, aluminum, iridium, platinum, molybdenum, zinc, or the like. The organic compound layer may be arranged between the first and second electrodes, and may be arranged in contact with the first and second electrodes. If a plurality of light emitting layers are provided, a charge generation portion may be arranged between the first light emitting layer and the second light emitting layer. The charge generation portion may contain an organic compound with a lowest unoccupied molecular orbital energy (LUMO) of −5.0 eV or less. The same applies to a case where a charge generating portion is provided between the second light emitting layer and the third light emitting layer.

### Protection Layer

A protection layer may be provided on the cathode. For example, by adhering glass provided with a moisture absorbing agent on the cathode, permeation of water or the like into the organic compound layer can be suppressed and occurrence of display defects can be suppressed. Furthermore, as another embodiment, a passivation layer made of silicon nitride or the like may be provided on the cathode to suppress permeation of water or the like into the organic compound layer. For example, the protection layer can be formed by forming the cathode, transferring it to another chamber without breaking the vacuum, and forming silicon nitride having a thickness of 2 μm by the CVD method. The protection layer may be provided using an atomic layer deposition (ALD) method after deposition of the protection layer using the CVD method. The material of the protection layer by the ALD method is not limited but can be silicon nitride, silicon oxide, aluminum oxide, or the like. Silicon nitride may further be formed by the CVD method on the protection layer formed by the ALD method. The protection layer formed by the ALD method may have a film thickness smaller than that of the protection layer formed by the CVD method. More specifically, the film thickness of the protection layer formed by the ALD method may be 50% or less, or 10% or less of that of the protection layer formed by the CVD method.

### Color Filter

A color filter may be provided on the protection layer. For example, a color filter considering the size of the organic light emitting element may be provided on another substrate, and the substrate with the color filter formed thereon may be bonded to the substrate with the organic light emitting element provided thereon. Alternatively, for example, a color filter may be patterned on the above-described protection layer using a photolithography technique. The color filter may be formed from a polymeric material.

### Planarizing Layer

A planarizing layer may be arranged between the color filter and the protection layer. The planarizing layer is provided to reduce unevenness of the layer below the planarizing layer. The planarizing layer may be called a material resin layer without limiting the purpose of the layer. The planarizing layer may be formed from an organic compound, and may be made of a low-molecular material or a polymeric material. In consideration of reduction of unevenness, a polymeric organic compound may be used for the planarizing layer.

The planarizing layers may be provided above and below the color filter. In that case, the same or different constituent materials may be used for these planarizing layers. More specifically, examples of the material of the planarizing layer include polyvinyl carbazole resin, polycarbonate resin, polyester resin, ABS resin, acrylic resin, polyimide resin, phenol resin, epoxy resin, silicone resin, and urea resin.

### Microlens

The organic light emitting device may include an optical member such as a microlens on the light emission side. The microlens can be made of acrylic resin, epoxy resin, or the like. The microlens can aim to increase the amount of light extracted from the organic light emitting device and control the direction of light to be extracted. The microlens can have a hemispherical shape. If the microlens has a hemispherical shape, among tangents contacting the hemisphere, there is a tangent parallel to the insulating layer, and the contact between the tangent and the hemisphere is the vertex of the microlens. The vertex of the microlens can be decided in the same manner even in an arbitrary sectional view. That is, among tangents contacting the semicircle of the microlens in a sectional view, there is a tangent parallel to the insulating layer, and the contact between the tangent and the semicircle is the vertex of the microlens.

Furthermore, the middle point of the microlens can also be defined. In the section of the microlens, a line segment from a point at which an arc shape ends to a point at which another arc shape ends is assumed, and the middle point of the line segment can be called the middle point of the microlens. A section for determining the vertex and the middle point may be a section perpendicular to the insulating layer.

The microlens includes a first surface including a convex portion and a second surface opposite to the first surface. The second surface can be arranged on the functional layer (light emitting layer) side of the first surface. For this configuration, the microlens needs to be formed on the light emitting device. If the functional layer is an organic layer, a process which produces high temperature in the manufacturing step of the microlens may be avoided. In addition, if it is configured to arrange the second surface on the functional layer side of the first surface, all the glass transition temperatures of an organic compound forming the organic layer may be 100° C. or more. For example, 130° C. or more is suitable.

### Counter Substrate

A counter substrate may be arranged on the planarizing layer. The counter substrate is called a counter substrate because it is provided at a position corresponding to the above-described substrate. The constituent material of the counter substrate can be the same as that of the above-described substrate. If the above-described substrate is the first substrate, the counter substrate can be the second substrate.

### Organic Layer

The organic compound layer (hole injection layer, hole transport layer, electron blocking layer, light emitting layer, hole blocking layer, electron transport layer, electron injection layer, and the like) forming the organic light emitting element according to an embodiment of the present disclosure may be formed by the method to be described below.

The organic compound layer forming the organic light emitting element according to the embodiment of the present disclosure can be formed by a dry process using a vacuum deposition method, an ionization deposition method, a sputtering method, a plasma method, or the like. Instead of the dry process, a wet process that forms a layer by dissolving a solute in an appropriate solvent and using a well-known coating method (for example, a spin coating method, a dipping method, a casting method, an LB method, an inkjet method, or the like) can be used.

Here, when the layer is formed by a vacuum deposition method, a solution coating method, or the like, crystallization or the like hardly occurs and excellent temporal stability is obtained. Furthermore, when the layer is formed using a coating method, it is possible to form the film in combination with a suitable binder resin.

Examples of the binder resin include polyvinyl carbazole resin, polycarbonate resin, polyester resin, ABS resin, acrylic resin, polyimide resin, phenol resin, epoxy resin, silicone resin, and urea resin. However, the binder resin is not limited to them.

One of these binder resins may be used singly as a homopolymer or a copolymer, or two or more of them may be used in combination. Furthermore, additives such as a well-known plasticizer, antioxidant, and an ultraviolet absorber may also be used as needed.

### Pixel Circuit

The light emitting device can include a pixel circuit connected to the light emitting element. The pixel circuit may be an active matrix circuit that individually controls light emission of the first and second light emitting elements. The active matrix circuit may be a voltage or current programing circuit. A driving circuit includes a pixel circuit for each pixel. The pixel circuit can include a light emitting element, a transistor for controlling light emission luminance of the light emitting element, a transistor for controlling a light emission timing, a capacitor for holding the gate voltage of the transistor for controlling the light emission luminance, and a transistor for connection to GND without intervention of the light emitting element.

The light emitting device includes a display region and a peripheral region arranged around the display region. The light emitting device includes the pixel circuit in the display region and a display control circuit in the peripheral region. The mobility of the transistor forming the pixel circuit may be smaller than that of a transistor forming the display control circuit.

The slope of the current-voltage characteristic of the transistor forming the pixel circuit may be smaller than that of the current-voltage characteristic of the transistor forming the display control circuit. The slope of the current-voltage characteristic can be measured by a so-called Vg-Ig characteristic.

The transistor forming the pixel circuit is a transistor connected to the light emitting element such as the first light emitting element.

### Pixel

The organic light emitting device includes a plurality of pixels. Each pixel includes sub-pixels that emit light components of different colors. The sub-pixels may include, for example, R, G, and B emission colors, respectively.

In each pixel, a region also called a pixel opening emits light. The pixel opening can have a size of 5 μm (inclusive) to 15 μm (inclusive). More specifically, the pixel opening can have a size of 11 μm, 9.5 μm, 7.4 μm, 6.4 μm, or the like.

A distance between the sub-pixels can be 10 μm or less, and can be, more specifically, 8 μm, 7.4 μm, or 6.4 μm.

The pixels can have a known arrangement form in a plan view. For example, the pixels may have a stripe arrangement, a delta arrangement, a pentile arrangement, or a Bayer arrangement. The shape of each sub-pixel in a plan view may be any known shape. For example, a quadrangle such as a rectangle or a rhombus, a hexagon, or the like may be possible. A shape which is not a correct shape but is close to a rectangle is included in a rectangle, as a matter of course. The shape of the sub-pixel and the pixel arrangement can be used in combination.

### Application of Organic Light Emitting Element of Embodiment of Present Disclosure

The organic light emitting element according to an embodiment of the present disclosure can be used as a constituent member of a display device or an illumination device. In addition, the organic light emitting element is applicable to the exposure light source of an electrophotographic image forming device, the backlight of a liquid crystal display device, a light emitting device including a color filter in a white light source, and the like.

The display device may be an image information processing device that includes an image input unit for inputting image information from an area CCD, a linear CCD, a memory card, or the like, and an information processing unit for processing the input information, and displays the input image on a display unit.

In addition, a display unit included in an image capturing device or an inkjet printer can have a touch panel function. The driving type of the touch panel function may be an infrared type, a capacitance type, a resistive film type, or an electromagnetic induction type, and is not particularly limited. The display device may be used for the display unit of a multifunction printer.

More details will be described next with reference to the accompanying drawings. FIG. 17A shows an example of the pixel 400 arranged in the light emitting device 500. The pixel includes sub-pixels 810 (pixels 400). The sub-pixels are divided into sub-pixels 810R, 810G, and 810B by emitted light components. The light emission colors may be discriminated by the wavelengths of light components emitted from the light emitting layers, or light emitted from each sub-pixel may be selectively transmitted or undergo color conversion by a color filter or the like. Each sub-pixel includes a reflective electrode 802 as the first electrode on an interlayer insulating layer 801, an insulating layer 803 covering the end of the reflective electrode 802, an organic compound layer 804 covering the first electrode and the insulating layer, a transparent electrode 805 as the second electrode, a protection layer 806, and a color filter 807.

The interlayer insulating layer 801 can include a transistor and a capacitive element arranged in the interlayer insulating layer 801 or a layer below it. The transistor and the first electrode can electrically be connected via a contact hole (not shown) or the like.

The insulating layer 803 can also be called a bank or a pixel isolation film. The insulating layer 803 covers the end of the first electrode, and is arranged to surround the first electrode. A portion of the first electrode where no insulating layer 803 is arranged is in contact with the organic compound layer 804 to form a light emitting region.

The organic compound layer 804 includes a hole injection layer 841, a hole transport layer 842, a first light emitting layer 843, a second light emitting layer 844, and an electron transport layer 845.

The second electrode may be a transparent electrode, a reflective electrode, or a semi-transmissive electrode.

The protection layer 806 suppresses permeation of water into the organic compound layer. The protection layer is shown as a single layer but may include a plurality of layers. Each layer can be an inorganic compound layer or an organic compound layer.

The color filter 807 is divided into color filters 807R, 807G, and 807B by colors. The color filters can be formed on a planarizing film (not shown). A resin protection layer (not shown) may be arranged on the color filters. The color filters can be formed on the protection layer 806. Alternatively, the color filters can be provided on the counter substrate such as a glass substrate, and then the substrate may be bonded.

The display device 800 (corresponding to the above-described light emitting device 500) shown in FIG. 17B is provided with an organic light emitting element 826 as an example of a light emitting element and a TFT 818 as an example of a transistor. A substrate 811 of glass, silicon, or the like is provided and an insulating layer 812 is provided on the substrate 811. The active element such as the TFT 818 is arranged on the insulating layer, and a gate electrode 813, a gate insulating film 814, and a semiconductor layer 815 of the active element are arranged. The TFT 818 further includes the semiconductor layer 815, a drain electrode 816, and a source electrode 817. An insulating film 819 is provided on the TFT 818. The source electrode 817 and an anode 821 forming the organic light emitting element 826 are connected via a contact hole 820 formed in the insulating film.

A method of electrically connecting the electrodes (anode and cathode) included in the organic light emitting element 826 and the electrodes (source electrode and drain electrode) included in the TFT is not limited to that shown in FIG. 17B. That is, one of the anode and cathode and one of the source electrode and drain electrode of the TFT are electrically connected. The TFT indicates a thin-film transistor.

In the display device 800 shown in FIG. 17B, an organic compound layer is illustrated as one layer. However, an organic compound layer 822 may include a plurality of layers. A first protection layer 824 and a second protection layer 825 are provided on a cathode 823 to suppress deterioration of the organic light emitting element.

A transistor is used as a switching element in the display device 800 shown in FIG. 17B, but another switching element may be used instead.

The transistor used in the display device 800 shown in FIG. 17B is not limited to a transistor using a single-crystal silicon wafer, and may be a thin-film transistor including an active layer on an insulating surface of a substrate. Examples of the active layer include single-crystal silicon, amorphous silicon, non-single-crystal silicon such as microcrystalline silicon, and a non-single-crystal oxide semiconductor such as indium zinc oxide and indium gallium zinc oxide. Note that a thin-film transistor is also called a TFT element.

The transistor included in the display device 800 shown in FIG. 17B may be formed in the substrate such as a silicon substrate. Forming the transistor in the substrate means forming the transistor by processing the substrate such as a silicon substrate. That is, when the transistor is included in the substrate, it can be considered that the substrate and the transistor are formed integrally.

The light emission luminance of the organic light emitting element according to this embodiment can be controlled by the TFT which is an example of a switching element, and the plurality of organic light emitting elements can be provided in a plane to display an image with the light emission luminances of the respective elements. Here, the switching element according to this embodiment is not limited to the TFT, and may be a transistor formed from low-temperature polysilicon or an active matrix driver formed on the substrate such as a silicon substrate. The term “on the substrate” may mean “in the substrate”. Whether to provide a transistor in the substrate or use a TFT is selected based on the size of the display unit. For example, if the size is about 0.5 inch, the organic light emitting element may be provided on the silicon substrate.

FIG. 18 is a schematic view showing an example of the display device using the light emitting device 500 according to this embodiment. A display device 1000 can include a touch panel 1003, a display panel 1005, a frame 1006, a circuit board 1007, and a battery 1008 between an upper cover 1001 and a lower cover 1009. Flexible printed circuits (FPCs) 1002 and 1004 are respectively connected to the touch panel 1003 and the display panel 1005. A control circuit including a logic circuit formed from transistors and the like is arranged on the circuit board 1007. The battery 1008 is unnecessary if the display device 1000 is not a portable apparatus. Even when the display device 1000 is a portable apparatus, the battery 1008 need not be provided at this position. The light emitting device 500 can be applied to the display panel 1005. The pixels 400 arranged in the light emitting device 500 functioning as the display panel 1005 are connected to the control circuit arranged on the circuit board 1007 and operate.

The display device 1000 shown in FIG. 18 can be used for a display unit of a photoelectric conversion device (also referred to as an image capturing device) including an optical unit having a plurality of lenses, and an image sensor for receiving light having passed through the optical unit and photoelectrically converting the light into an electric signal. The photoelectric conversion device can include a display unit for displaying information acquired by the image sensor. In addition, the display unit can be either a display unit exposed outside the photoelectric conversion device, or a display unit arranged in the finder. The photoelectric conversion device can be a digital camera or a digital video camera.

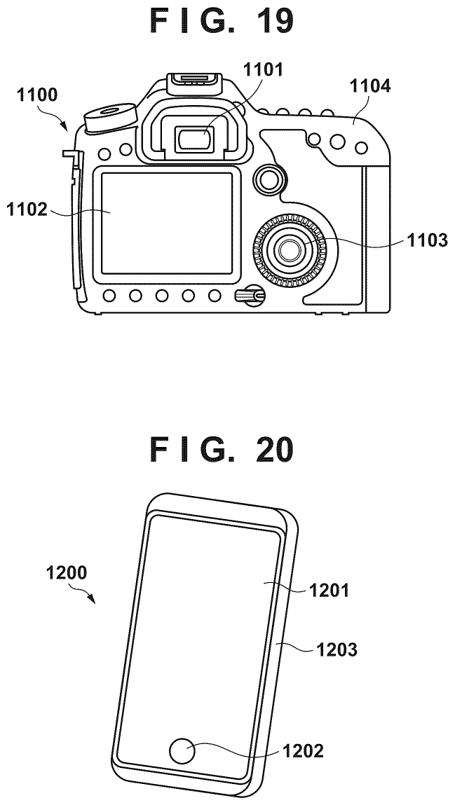

FIG. 19 is a schematic view showing an example of the photoelectric conversion device using the light emitting device 500 according to this embodiment. A photoelectric conversion device 1100 can include a viewfinder 1101, a rear display 1102, an operation unit 1103, and a housing 1104. The photoelectric conversion device 1100 can also be called an image capturing device. The light emitting device 500 according to this embodiment can be applied to the viewfinder 1101 or the rear display 1102 as a display unit. In this case, the light emitting device 500 can display not only an image to be captured but also environment information, image capturing instructions, and the like. Examples of the environment information are the intensity and direction of external light, the moving velocity of an object, and the possibility that an object is covered with an obstacle.

Since the timing suitable for image capturing is a very short time in many cases, it is better to display the information as soon as possible. Therefore, the light emitting device 500 in which the pixel 400 including the light emitting element using the organic light emitting material such as an organic EL element is arranged may be used for the viewfinder 1101 or the rear display 1102. This is so because the organic light emitting material has a high response speed. The light emitting device 500 using the organic light emitting material can be used for the devices that require a high display speed more suitably than for the liquid crystal display device.

The photoelectric conversion device 1100 includes an optical unit (not shown). This optical unit has a plurality of lenses, and forms an image on a photoelectric conversion element (not shown) that receives light having passed through the optical unit and is accommodated in the housing 1104. The focal points of the plurality of lenses can be adjusted by adjusting the relative positions. This operation can also automatically be performed.

The light emitting device 500 may be applied to a display unit of an electronic apparatus. At this time, the display unit can have both a display function and an operation function. Examples of the portable terminal are a portable phone such as a smartphone, a tablet, and a head mounted display.

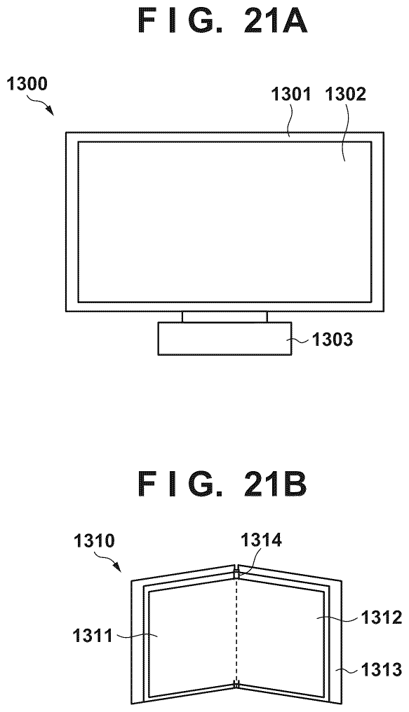

FIG. 20 is a schematic view showing an example of an electronic apparatus using the light emitting device 500 according to this embodiment. An electronic apparatus 1200 includes a display unit 1201, an operation unit 1202, and a housing 1203. The housing 1203 can accommodate a circuit, a printed board having this circuit, a battery, and a communication unit. The operation unit 1202 can be a button or a touch-panel-type reaction unit. The operation unit 1202 can also be a biometric authentication unit that performs unlocking or the like by authenticating the fingerprint. The portable apparatus including the communication unit can also be regarded as a communication apparatus. The light emitting device 500 according to this embodiment can be applied to the display unit 1201.

FIGS. 21A and 21B are schematic views showing examples of the display device using the light emitting device 500 according to this embodiment. FIG. 21A shows a display device such as a television monitor or a PC monitor. A display device 1300 includes a frame 1301 and a display unit 1302. The light emitting device 500 according to this embodiment can be applied to the display unit 1302. The display device 1300 can include a base 1303 that supports the frame 1301 and the display unit 1302. The base 1303 is not limited to the form shown in FIG. 21A. For example, the lower side of the frame 1301 may also function as the base 1303. In addition, the frame 1301 and the display unit 1302 can be bent. The radius of curvature in this case can be 5,000 mm (inclusive) to 6,000 mm (inclusive).

FIG. 21B is a schematic view showing another example of the display device using the light emitting device 500 according to this embodiment. A display device 1310 shown in FIG. 21B can be folded, and is a so-called foldable display device. The display device 1310 includes a first display unit 1311, a second display unit 1312, a housing 1313, and a bending point 1314. The light emitting device 500 according to this embodiment can be applied to each of the first display unit 1311 and the second display unit 1312. The first display unit 1311 and the second display unit 1312 can also be one seamless display device. The first display unit 1311 and the second display unit 1312 can be divided by the bending point. The first display unit 1311 and the second display unit 1312 can display different images, and can also display one image together.

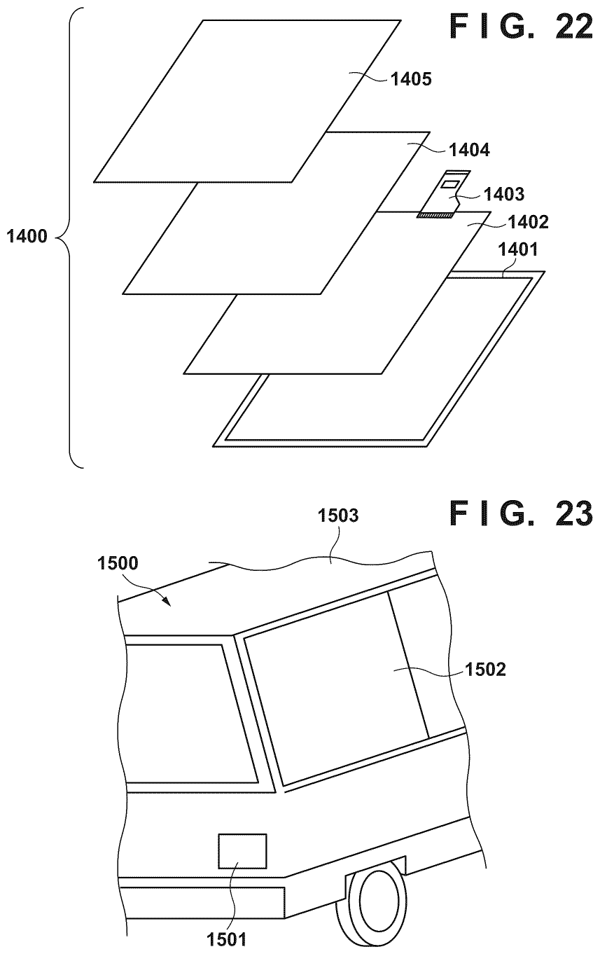

FIG. 22 is a schematic view showing an example of the illumination device using the light emitting device 500 according to this embodiment. An illumination device 1400 can include a housing 1401, a light source 1402, a circuit board 1403, an optical film 1404, and a light diffusing unit 1405. The light emitting device 500 according to this embodiment can be applied to the light source 1402. The optical film 1404 can be a filter that improves the color rendering of the light source. When performing lighting-up or the like, the light diffusing unit 1405 can throw the light of the light source over a broad range by effectively diffusing the light. The illumination device can also include a cover on the outermost portion, as needed. The illumination device 1400 can include both or one of the optical film 1404 and the light diffusing unit 1405.

The illumination device 1400 is, for example, a device for illuminating the interior of the room. The illumination device 1400 can emit white light, natural white light, or light of any color from blue to red. The illumination device 1400 can also include a light control circuit for controlling these light components. The illumination device 1400 can also include a power supply circuit connected to the light emitting device 500 functioning as the light source 1402. The power supply circuit is a circuit for converting an AC voltage into a DC voltage. White has a color temperature of 4,200 K, and natural white has a color temperature of 5,000 K. The illumination device 1400 may also include a color filter. In addition, the illumination device 1400 can include a heat radiation unit. The heat radiation unit radiates the internal heat of the device to the outside of the device, and examples are a metal having a high specific heat and liquid silicon.

FIG. 23 is a schematic view of an automobile having a taillight as an example of a vehicle lighting appliance using the light emitting device 500 according to this embodiment. An automobile 1500 has a taillight 1501, and can have a form in which the taillight 1501 is turned on when performing a braking operation or the like. The light emitting device 500 according to this embodiment can be used as a headlight serving as a vehicle lighting appliance. The automobile is an example of a moving body, and the moving body may be a ship, a drone, an aircraft, a railroad car, an industrial robot, or the like. The moving body may include a main body and a lighting appliance provided in the main body. The lighting appliance may be used to make a notification of the current position of the main body.

The light emitting device 500 according to this embodiment can be applied to the taillight 1501. The taillight 1501 can include a protection member for protecting the light emitting device 500 functioning as the taillight 1501. The material of the protection member is not limited as long as the material is a transparent material with a strength that is high to some extent, and an example is polycarbonate. The protection member may be made of a material obtained by mixing a furandicarboxylic acid derivative, an acrylonitrile derivative, or the like in polycarbonate.

The automobile 1500 can include a vehicle body 1503, and a window 1502 attached to the vehicle body 1503. This window can be a window for checking the front and back of the automobile, and can also be a transparent display such as a head-up display. For this transparent display, the light emitting device 500 according to this embodiment may be used. In this case, the constituent materials of the electrodes and the like of the light emitting device 500 are formed by transparent members.

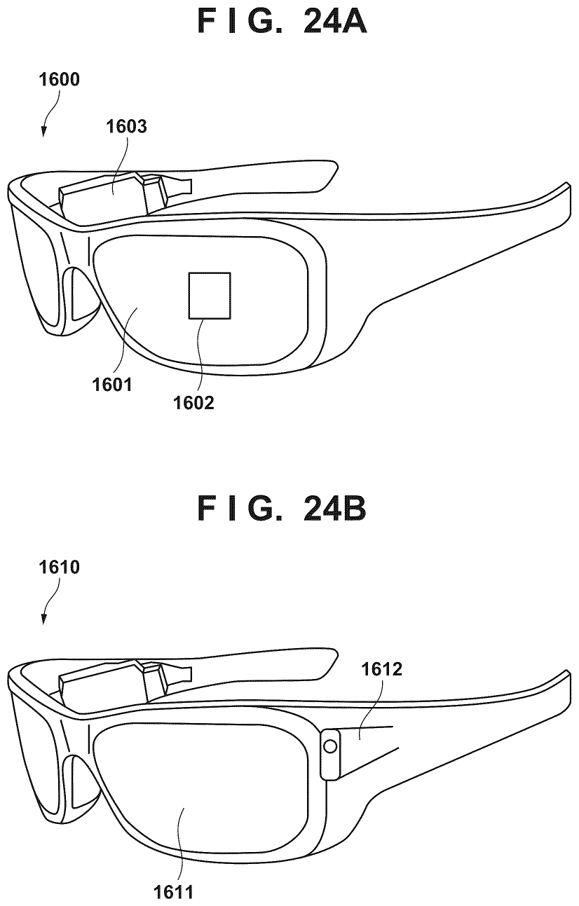

Further application examples of the light emitting device 500 according to this embodiment will be described with reference to FIGS. 24A and 24B. The light emitting device 500 can be applied to a system that can be worn as a wearable device such as smartglasses, a Head Mounted Display (HMD), or a smart contact lens. An image capturing display device used for such application examples includes an image capturing device capable of photoelectrically converting visible light and a light emitting device capable of emitting visible light.

Glasses 1600 (smartglasses) according to one application example will be described with reference to FIG. 24A. An image capturing device 1602 such as a CMOS sensor or an SPAD is provided on the surface side of a lens 1601 of the glasses 1600. In addition, the light emitting device 500 according to this embodiment is provided on the back surface side of the lens 1601.

The glasses 1600 further include a control device 1603. The control device 1603 functions as a power supply that supplies electric power to the image capturing device 1602 and the light emitting device 500 according to each embodiment. In addition, the control device 1603 controls the operations of the image capturing device 1602 and the light emitting device 500. An optical system configured to condense light to the image capturing device 1602 is formed on the lens 1601.

Glasses 1610 (smartglasses) according to one application example will be described with reference to FIG. 24B. The glasses 1610 include a control device 1612, and an image capturing device corresponding to the image capturing device 1602 and the light emitting device 500 are mounted on the control device 1612. The image capturing device in the control device 1612 and an optical system configured to project light emitted from the light emitting device 500 are formed in a lens 1611, and an image is projected to the lens 1611. The control device 1612 functions as a power supply that supplies electric power to the image capturing device and the light emitting device 500, and controls the operations of the image capturing device and the light emitting device 500. The control device 1612 may include a line-of-sight detection unit that detects the line of sight of a wearer. The detection of a line of sight may be done using infrared rays. An infrared ray emitting unit emits infrared rays to an eyeball of the user who is gazing at a displayed image. An image capturing unit including a light receiving element detects reflected light of the emitted infrared rays from the eyeball, thereby obtaining a captured image of the eyeball. A reduction unit for reducing light from the infrared ray emitting unit to the display unit in a planar view is provided, thereby reducing deterioration of image quality.

The line of sight of the user to the displayed image is detected from the captured image of the eyeball obtained by capturing the infrared rays. An arbitrary known method can be applied to the line-of-sight detection using the captured image of the eyeball. As an example, a line-of-sight detection method based on a Purkinje image obtained by reflection of irradiation light by a cornea can be used.

More specifically, line-of-sight detection processing based on pupil center corneal reflection is performed. Using pupil center corneal reflection, a line-of-sight vector representing the direction (rotation angle) of the eyeball is calculated based on the image of the pupil and the Purkinje image included in the captured image of the eyeball, thereby detecting the line-of-sight of the user.

The light emitting device 500 according to the embodiment of the present disclosure can include an image capturing device including a light receiving element, and control a displayed image based on the line-of-sight information of the user from the image capturing device.

More specifically, the light emitting device 500 decides a first visual field region at which the user is gazing and a second visual field region other than the first visual field region based on the line-of-sight information. The first visual field region and the second visual field region may be decided by the control device of the light emitting device 500, or those decided by an external control device may be received. In the display region of the light emitting device 500, the display resolution of the first visual field region may be controlled to be higher than the display resolution of the second visual field region. That is, the resolution of the second visual field region may be lower than that of the first visual field region.

In addition, the display region includes a first display region and a second display region different from the first display region, and a region of higher priority is decided from the first display region and the second display region based on line-of-sight information. The first display region and the second display region may be decided by the control device of the light emitting device 500, or those decided by an external control device may be received. The resolution of the region of higher priority may be controlled to be higher than the resolution of the region other than the region of higher priority. That is, the resolution of the region of relatively low priority may be low.

Note that AI may be used to decide the first visual field region or the region of higher priority. The AI may be a model configured to estimate the angle of the line of sight and the distance to a target ahead the line of sight from the image of the eyeball using the image of the eyeball and the direction of actual viewing of the eyeball in the image as supervised data. The AI program may be held by the light emitting device 500, the image capturing device, or an external device. If the external device holds the AI program, it is transmitted to the light emitting device 500 via communication.

When performing display control based on line-of-sight detection, smartglasses further including an image capturing device configured to capture the outside can be applied. The smartglasses can display captured outside information in real time.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

This application claims the benefit of Japanese Patent Application No. 2024-030644, filed Feb. 29, 2024, which is hereby incorporated by reference herein in its entirety.

What is claimed is:

1. A light emitting device comprising a plurality of pixels, wherein
each of the plurality of pixels includes a first electrode arranged on a substrate, a second electrode arranged between the first electrode and the substrate, an organic functional layer including a light emitting layer arranged between the first electrode and the second electrode, and a reflective layer arranged between the second electrode and the substrate,
the reflective layer has a first surface on a side of the second electrode, and a second surface on a side of the substrate, and
an unevenness of the first surface is smaller than an unevenness of the second surface.

2. The device according to claim 1, further including a conductive layer arranged between the substrate and the reflective layer and in contact with the second surface.

3. The device according to claim 1, wherein the reflective layer and the second electrode are electrically connected to each other.

4. The device according to claim 1, wherein
each of the plurality of pixels further includes a structure which is arranged between the reflective layer and the substrate and in which a wiring pattern is arranged in an insulator, and a transistor arranged in the substrate, and
the reflective layer is electrically connected to the transistor via the wiring pattern.

5. The device according to claim 1, wherein
each of the plurality of pixels further includes a structure which is arranged between the reflective layer and the substrate and in which a wiring pattern is arranged in an insulator, a transistor arranged in the substrate, and a conductive pattern which is arranged on a side of the insulator opposite to the substrate and is electrically connected to the second electrode,
the reflective layer and the conductive pattern are in contact with the insulator, and
the conductive pattern is electrically connected to the transistor via the wiring pattern.

6. The device according to claim 5, wherein the reflective layer and the conductive pattern contain a same material.

7. The device according to claim 1, wherein
each of the plurality of pixels further includes an insulating layer arranged between the second electrode and the reflective layer,
the plurality of pixels include a first pixel and a second pixel, and
a thickness of the insulating layer is different between the first pixel and the second pixel.

8. The device according to claim 7, wherein a distance between the reflective layer and the substrate in the first pixel is different from a distance between the reflective layer and the substrate in the second pixel.

9. The device according to claim 7, wherein a difference between a distance between the reflective layer and the substrate in the first pixel and distance between the reflective layer and the substrate in the second pixel is smaller than a difference between a thickness of the insulating layer in the first pixel and a thickness of the insulating layer in the second pixel.

10. The device according to claim 7, wherein
the plurality of pixels further include a third pixel, and
a thickness of the insulating layer in the third pixel is different from a thickness of the insulating layer in each of the first pixel and the second pixel.

11. The device according to claim 1, wherein the reflective layer contains a conductive material.

12. The device according to claim 1, wherein the reflective layer contains aluminum.

13. A display device comprising the light emitting device according to claim 1, and a control circuit connected to the light emitting device.

14. A photoelectric conversion device comprising an optical unit including a plurality of lenses, an image sensor configured to receive light having passed through the optical unit, and a display unit configured to display an image, wherein the display unit includes the light emitting device according to claim 1.

15. An electronic apparatus comprising a housing provided with a display unit, and a communication unit provided in the housing and configured to perform external communication,
wherein the display unit includes the light emitting device according to claim 1.

16. An illumination device comprising a light source, and at least one of a light diffusing unit and an optical film,
wherein the light source includes the light emitting device according to claim 1.

17. A moving body comprising a main body, and a lighting appliance provided in the main body,
wherein the lighting appliance includes the light emitting device according to claim 1.

18. A wearable device comprising a display device configured to display an image,
wherein the display device includes the light emitting device according to claim 1.

19. A manufacturing method of a light emitting device including a plurality of pixels, comprising:
preparing a substrate including a structure where a wiring pattern is arranged in an insulator;
forming a first insulating layer on a support substrate;
forming a reflective layer on the first insulating layer;
forming, on the first insulating layer and the reflective layer, a bonding layer including a second insulating layer and a bonding pattern;
bonding the structure and the bonding layer;
exposing the first insulating layer by at least partially removing the support substrate after the bonding; and
forming a first electrode, an organic functional layer, and a second electrode on the first insulating layer exposed by the exposing.

20. The method according to claim 19, wherein
the plurality of pixels include a first pixel and a second pixel, and
the forming the first insulating layer includes
forming a material layer of the first insulating layer on the support substrate, and
etching the material layer so as to have different film thicknesses in a portion of the material layer constituting the first pixel and a portion of the material layer constituting the second pixel.

21. The method according to claim 19, wherein
the plurality of pixels include a first pixel and a second pixel,
the method further comprises forming, on the support substrate, a structure layer having different film thicknesses in a portion corresponding to the first pixel and a portion corresponding to the second pixel, before the forming the first insulating layer,
the first insulating layer is formed on the structure layer, and
the exposing includes exposing the first insulating layer by at least partially removing the support substrate and the structure layer.
